(19) United States
(12) Patent Application Publication
(10) Pub. No.: US 2025/0338708 A1
(43) Pub. Date: Oct. 30, 2025

(54) LIGHT-EMITTING ELEMENT PRODUCTION METHOD AND LIGHT-EMITTING ELEMENT

(71) Applicant: Sharp Display Technology Corporation, Kameyama City, Mie (JP)

(72) Inventor: TAKAHIRO DOE, Sakai City, Osaka (JP)

(21) Appl. No.: 18/867,427

(22) PCT Filed: Jul. 13, 2022
(86) PCT No.: PCT/JP2022/027509

§ 371 Date: Nov. 19, 2024

(51) Int. Cl. H10K 50/115; H10K 71/15

(52) U.S. Cl. CPC H10K 50/115; H10K 71/15

(57) ABSTRACT

A manufacturing method for a light-emitting element includes: forming a light-emitting layer including a quantum dot; forming an intermediate layer including a metal halide having solubility in water at 25° C. of 2.5 mg/100 g or more on the light-emitting layer; and forming a carrier transport layer on the intermediate layer. Forming the carrier transport layer includes applying the intermediate layer with a carrier transporting material dispersion including a carrier transporting material and a first solvent, and removing the first solvent.

### TECHNICAL FIELD

The disclosure relates to a manufacturing method for a light-emitting element and a light-emitting element.

### BACKGROUND ART

A surface of a quantum dot is generally provided with a ligand (modification group) for the purpose of protection of the quantum dot, improvement of dispersibility in a solvent, and the like. As the ligand, an organic ligand is generally used because of excellent dispersibility of quantum dots in a quantum dot dispersion. However, an organic ligand using an insulating organic material can be an inhibiting factor of carrier injection in a charge (carrier) injection type light-emitting element including a quantum dot in a light-emitting layer.

Therefore, in recent years, an inorganic ligand attracts attention as a ligand to substitute an organic ligand. The inorganic ligand has higher stability than the organic ligand and is excellent in carrier injection properties. For example, PTL 1 discloses a stable quantum dot composition including a quantum dot and a fluoride-including ligand such as ZnF₂ bonded to the surface of the quantum dot by ligand substitution of an organic ligand on the surface of the quantum dot.

### CITATION LIST

### Patent Literature

PTL 1: JP 2020-180278 A

### SUMMARY OF INVENTION

### Technical Problem

When an electron transport layer including, for example, ZnO nanoparticles as a carrier transporting material is layered on a light-emitting layer including a quantum dot as a carrier transport layer, alcohol is used as a solvent in a carrier transporting material dispersion, which is a coating liquid including the carrier transporting material, used for formation of the carrier transport layer.

However, some metal halides such as ZnF₂ have very low solubility in a solvent such as alcohol used for formation of such a carrier transport layer. In a case where the quantum dot has Zn—F bond on the surface as in the case of using a ZnF₂ ligand as an inorganic ligand, the surface tension of the light-emitting layer surface including the quantum dot is smaller than the surface tension of the solvent used for formation of a carrier transport layer layered on the light-emitting layer. Therefore, a light-emitting layer including a quantum dot ligand-substituted with a fluorine ligand such as ZnF₂ has poor wettability of a carrier transporting material dispersion used for formation of a carrier transport layer layered on the light-emitting layer. As a result, the layer thickness of the carrier transport layer formed on the light-emitting layer becomes non-uniform, and the element characteristic or reliability of the light-emitting element deteriorates.

In particular, when it is attempted to obtain a sufficient fluorine substitution amount, the wettability of the carrier transporting material dispersion further deteriorates by a metal halide layer including an excessive fluorine ligand (in other words, excess metal halide). In this case, the layer thickness of the carrier transport layer formed on the light-emitting layer becomes further non-uniform, and the element characteristic or reliability of the light-emitting element further deteriorates.

On the other hand, since the organic ligand can be an inhibiting factor of carrier injection as described above, when only ligand removal is performed in place of ligand substitution in order to facilitate carrier injection, the physical properties of bulk of the quantum dot become apparent. When the surface of the ligandless quantum dot comes into direct contact with the carrier transporting material dispersion in this manner, there is a possibility that a problem of wettability of the carrier transporting material dispersion with respect to the light-emitting layer occurs. When the surface of the ligandless quantum dot is exposed, the luminous efficiency may decrease. Therefore, it is desirable that a ligand is present on the surface of the quantum dot, but when a carrier transport layer is layered on a light-emitting layer including a quantum dot, there is the above-described problem.

One aspect of the disclosure has been made in view of the above problems, and an object of the disclosure is to provide a manufacturing method for a light-emitting element that can improve wettability of a carrier transporting material dispersion with respect to a light-emitting layer, and manufacture a light-emitting element having good layer thickness uniformity and excellent light-emission characteristics and reliability, and such a light-emitting element.

### Solution to Problem

In order to solve the above problems, a manufacturing method for a light-emitting element according to one aspect of the disclosure includes: forming a light-emitting layer; forming an intermediate layer including a first metal halide on the light-emitting layer; and forming a carrier transport layer on the intermediate layer, in which the forming the carrier transport layer includes applying a carrier transporting material dispersion including a carrier transporting material and a first solvent onto the intermediate layer, and removing the first solvent, in the forming the intermediate layer, an intermediate layer including, as the first metal halide, a metal halide having solubility in water at 25° C. of 2.5 mg/100 g or more is formed, and in the forming the light-emitting layer, as the light-emitting layer, (1) a light-emitting layer including a quantum dot and a second metal halide having solubility in water at 25° C. of less than 2.5 mg/100 g is formed, or (2) a light-emitting layer including the quantum dot, the light-emitting layer being an organic ligandless light-emitting layer is formed.

In order to solve the above problems, a manufacturing method for a light-emitting element according to one aspect of the disclosure includes: forming a light-emitting layer; and forming a carrier transport layer on the light-emitting layer, in which the forming the carrier transport layer includes applying a carrier transporting material dispersion including a carrier transporting material, a first solvent, and a first metal halide onto the light-emitting layer, and removing the first solvent, in applying the carrier transporting material dispersion, a metal halide having solubility in water at 25° C. of 2.5 mg/100 g or more is used as the first metal halide, and in the forming the light-emitting layer, as the light-emitting layer, (1) a light-emitting layer including a quantum dot and a second metal halide having solubility in water at 25° C. of less than 2.5 mg/100 g is formed, or (2) a light-emitting layer including the quantum dot, the light-emitting layer being an organic ligandless light-emitting layer is formed.

In order to solve the above problems, a light-emitting element according to one aspect of the disclosure includes: a light-emitting layer including a quantum dot and a first metal halide, in which (1) an intermediate layer including the first metal halide and a carrier transport layer including a carrier transporting material are provided adjacent to each other in this order from the light-emitting layer side, or (2) a carrier transport layer including a carrier transporting material and the first metal halide is provided adjacent to the light-emitting layer on the light-emitting layer, and solubility of the first metal halide in water at 25° C. is 2.5 mg/100 g or more.

### Advantageous Effects of Disclosure

According to one aspect of the disclosure, it is possible to provide a manufacturing method for a light-emitting element that can improve wettability of a carrier transporting material dispersion with respect to a light-emitting layer, and manufacture a light-emitting element having good layer thickness uniformity and excellent light-emission characteristics and reliability, and such a light-emitting element.

### BRIEF DESCRIPTION OF DRAWINGS

FIG. 1 is a flowchart showing an example of a manufacturing method for a light-emitting element according to a first embodiment.

FIG. 2 is a cross-sectional view illustrating a schematic configuration of a light-emitting element according to the first embodiment.

FIG. 3 is a cross-sectional view illustrating a schematic configuration of a quantum dot in the light-emitting element illustrated in FIG. 2.

FIG. 4 is another cross-sectional view illustrating a schematic configuration of a quantum dot in the light-emitting element illustrated in FIG. 2.

FIG. 5 is a flowchart showing an example of a light-emitting layer formation shown in FIG. 1.

FIG. 6 is a flowchart showing another example of the light-emitting layer formation shown in FIG. 1.

FIG. 7 is a cross-sectional view illustrating a schematic configuration of a main part in intermediate layer formation and electron transport layer formation shown in FIG. 1.

FIG. 8 is an energy band diagram for explaining an electron injection barrier in a case where a metal halide is not present between a shell of a quantum dot and an electron transport layer.

FIG. 9 is an energy band diagram for explaining an electron injection barrier in a case where a metal halide is present between a shell of a quantum dot and an electron transport layer.

FIG. 10 is a table showing band gaps and solubility of main metal halides in water at 25° C.

FIG. 11 is a view illustrating an energy level of each layer of a light-emitting element using a blue quantum dot and having a metal halide band gap of about 4.4 eV.

FIG. 12 is a view illustrating an energy level of each layer of a light-emitting element using a red quantum dot and having a metal halide band gap of about 5.2 eV.

FIG. 13 is a cross-sectional view illustrating an example of a schematic configuration of a light-emitting element according to a first modified example of the first embodiment.

FIG. 14 is a flowchart showing an example of a manufacturing method for a light-emitting element according to the first modified example of the first embodiment.

FIG. 15 is a flowchart showing an example of a manufacturing method for a light-emitting element according to a second modified example of the first embodiment.

FIG. 16 is a flowchart showing another example of light-emitting layer formation according to the second modified example of the first embodiment.

FIG. 17 is a flowchart showing an example of the manufacturing method for a light-emitting element according to the second embodiment.

FIG. 18 is a cross-sectional view illustrating a schematic configuration of a light-emitting element according to the second embodiment.

FIG. 19 is a flowchart showing an example of a manufacturing method for a light-emitting element according to the first modified example of the second embodiment.

FIG. 20 is a flowchart showing an example of a manufacturing method for a light-emitting element according to the second modified example of the second embodiment.

### DESCRIPTION OF EMBODIMENTS

Hereinafter, embodiments of the disclosure will be described in detail. Hereinafter, a layer formed by a process prior to a layer of a comparison target is called a “lower layer”, and a layer formed by a process subsequent to the layer of the comparison target is called an “upper layer”. In the following description, the description “A to B” regarding two numerals A and B means “equal to or greater than A and equal to or less than B” unless otherwise specified.

### First Embodiment

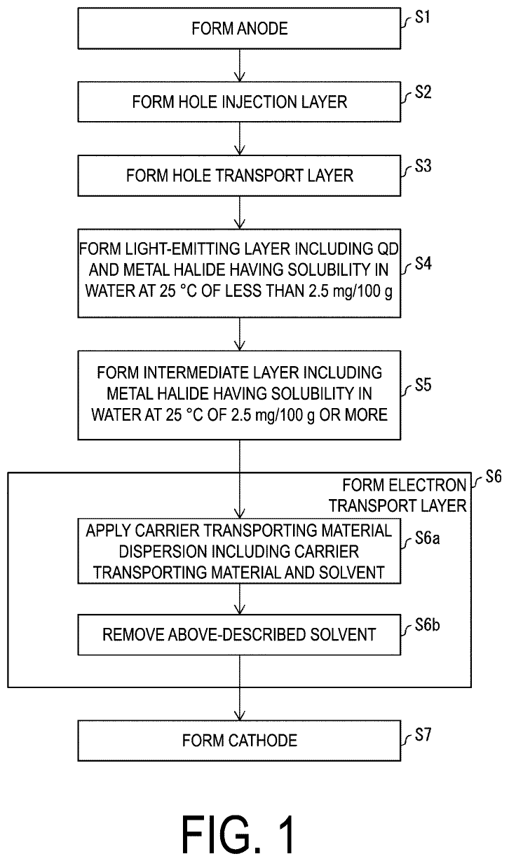

One embodiment of the disclosure will be described below with reference to FIGS. 1 to 16. Note that in the present embodiment, a method of manufacturing a light-emitting element in which an intermediate layer including a metal halide (first metal halide) and a carrier transport layer including a carrier transporting material are provided on a light-emitting layer adjacent to each other in this order from the light-emitting layer side (i.e., the lower layer side) will be described. A light-emitting element according to the disclosure is a quantum dot light-emitting diode (QLED) using a quantum dot as a light-emitting material in a light-emitting layer. In the disclosure, a layer between the light-emitting layer and the carrier transport layer is called an intermediate layer.

A manufacturing method for a light-emitting element according to the present embodiment includes: forming a light-emitting layer; forming an intermediate layer including a first metal halide on the light-emitting layer; and forming a carrier transport layer on the intermediate layer, in which the forming the carrier transport layer includes applying the intermediate layer with a carrier transporting material dispersion including a carrier transporting material and a first solvent, and removing the first solvent. In the forming the intermediate layer, an intermediate layer including, as the first metal halide, a metal halide having solubility in water at 25° C. of 2.5 mg/100 g or more is formed, and
in the forming the light-emitting layer, as the light-emitting layer, (1) a light-emitting layer including a quantum dot and a second metal halide having solubility in water at 25° C. of less than 2.5 mg/100 g is formed, or (2) a light-emitting layer including the quantum dot and being organic ligandless is formed. Note that in the disclosure, the solubility refers to the saturated solubility weight of the metal halide alone at 25° C.

Hereinafter, a case of forming a light-emitting layer including a quantum dot and the second metal halide as the light-emitting layer in the forming the light-emitting layer will be described as an example. In the following description, a case where the carrier transport layer formed on the intermediate layer is an electron transport layer will be described as an example. In the following description, a case where the light-emitting element has a conventional structure in which an anode is a lower layer electrode and a cathode is an upper layer electrode, and includes a hole injection layer, a hole transport layer, a light-emitting layer, an intermediate layer, and an electron transport layer as function layers between the anode and the cathode will be described as an example. Note that in the disclosure, the layers between the anode and the cathode are collectively called a function layer.

However, the light-emitting element according to the present embodiment is not limited to this, and may have an inverted structure in which the cathode is a lower layer electrode and the anode is an upper layer electrode, for example. As described above, when the carrier transport layer formed on the intermediate layer is an electron transport layer, the light-emitting element according to the present embodiment may be provided with the intermediate layer and the electron transport layer adjacent to each other in this order from the light-emitting layer side on the light-emitting layer. Therefore, when the carrier transport layer formed on the intermediate layer is an electron transport layer, the hole injection layer and the hole transport layer may be provided or needs not be provided. Therefore, the light-emitting element may have a configuration in which at least one of the hole injection layer and the hole transport layer is not provided, or may have a configuration in which a function layer other than the function layers is provided between the anode and the cathode.

Hereinafter, the light-emitting layer may be called “EML”, the carrier transport layer may be called “CTL”, the electron transport layer may be called “ETL”, the hole transport layer may be called “HTL”, the hole injection layer may be called “HIL”, and the intermediate layer may be called “IL”. The quantum dot may be called “QD”.

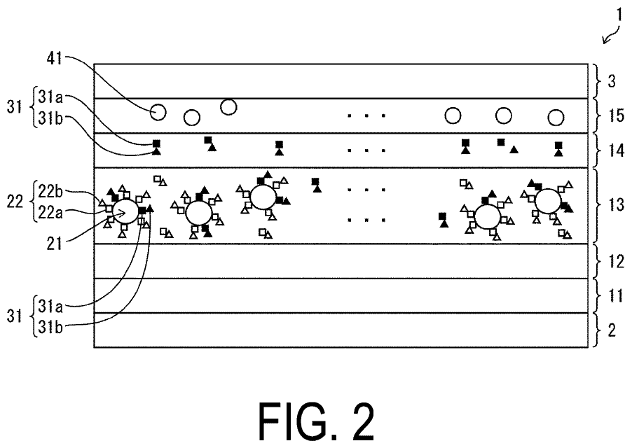

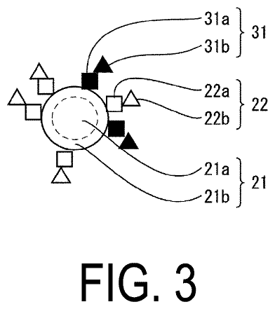

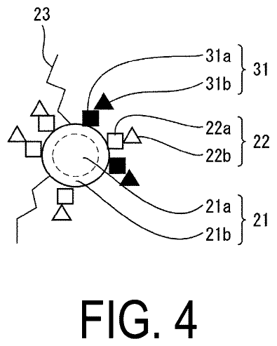

FIG. 1 is a flowchart showing an example of a manufacturing method of a light-emitting element 1 according to the present embodiment. FIG. 2 is a cross-sectional view illustrating a schematic configuration of the light-emitting element 1 according to the present embodiment. FIG. 3 is a cross-sectional view illustrating a schematic configuration of a QD 21 in the light-emitting element 1 illustrated in FIG. 2. FIG. 4 is another cross-sectional view illustrating a schematic configuration of the QD 21 in the light-emitting element 1 illustrated in FIG. 2.

As illustrated in FIG. 2, the light-emitting element 1 according to the present embodiment has a configuration in which, as an example, an anode 2, an HIL 11, an HTL 12, an EML 13, an IL 14, an ETL 15, and a cathode 3 are provided in this order from the lower layer side (e.g., a side of a support body not illustrated such as a substrate). Each layer from the anode 2 to the cathode 3 is generally supported by a substrate as a support body. Note that although illustration and description are omitted, the light-emitting element 1 may include a function layer not illustrated other than the HIL 11, the HTL 12, the EML 13, the IL 14, and the ETL 15 between the anode 2 and the cathode 3.

In the manufacturing method of the light-emitting element 1 according to the present embodiment, as shown in FIGS. 1 and 2, first, the anode 2 is formed as a lower layer electrode on a substrate not illustrated (step S1, lower layer electrode formation, anode formation). Subsequently, the HIL 11 is formed (step S2, hole injection layer formation). Subsequently, the HTL 12 is formed (step S3, hole transport layer formation). Subsequently, the EML 13 including the QD 21 and a metal halide 22 (second metal halide, inorganic ligand) having solubility in water at 25° C. of less than 2.5 mg/100 g is formed (step S4, light-emitting layer formation). Subsequently, the IL 14 including a metal halide 31 (first metal halide) having solubility in water at 25° C. of 2.5 mg/100 g or more is formed on the EML 13 (step S5, intermediate layer formation). Subsequently, the ETL 15 is formed on the IL 14 (step S6, carrier transport layer formation, electron transport layer formation). In step S6, as shown in FIG. 1, first, the IL 14 is applied with a carrier transporting material dispersion including a carrier transporting material 41 and a solvent (first solvent), thereby forming a coating film of the carrier transporting material dispersion (step S6a, carrier transporting material dispersion application). Subsequently, the coating film is heated or the like to remove the solvent included in the coating film, that is, the solvent (first solvent) included in the applied carrier transporting material dispersion (step S6b, first solvent removal). Due to this, the ETL 15 including the carrier transporting material 41 is formed on the IL 14. Subsequently, the cathode 3 is formed as an upper layer electrode on the ETL 15 (step S7, upper layer electrode formation, cathode formation). This forms the light-emitting element 1 illustrated in FIG. 2. More details are described below.

The anode 2 is an electrode that includes a conductive material and supplies a hole to the EML 13 when applied with a voltage. The cathode 3 is an electrode that includes a conductive material and supplies an electron to the EML 13 when applied with a voltage. At least one of the anode 2 and the cathode 3 is a light-transmissive electrode. Note that any one of the anode 2 and the cathode 3 may be a so-called reflective electrode having light reflectivity. In the light-emitting element 1, light can be extracted from the side of the light-transmissive electrode.

For example, in a case where the light-emitting element 1 is a top-emission type light-emitting element that emits light from an upper layer electrode side, a light-transmissive electrode is used as the upper layer electrode, and a reflective electrode is used as the lower layer electrode. On the other hand, in a case where the light-emitting element 1 is a bottom-emission type light-emitting element that emits light from a lower layer electrode side, a light-transmissive electrode is used as the lower layer electrode, and a reflective electrode is used as the lower layer electrode.

The light-transmissive electrode is formed of a conductive light-transmissive material such as, for example, indium tin oxide (ITO), indium zinc oxide (IZO), silver nanowire (AgNW), a thin film of magnesium-silver (MgAg) alloy, or a thin film of Ag.

On the other hand, the reflective electrode is formed of a conductive light-reflective material such as, for example, a metal such as Ag, Al, or Cu, or an alloy including these metals. Note that the reflective electrode may be provided by layering a layer made of the light-transmissive material and a layer made of the light-reflective material.

For the formation of the anode 2 in step S1 and the formation of the cathode 3 in step S5, for example, a vapor deposition method, a sputtering method, or the like is used. The anode 2 can be formed by depositing the conductive material onto a substrate not illustrated, for example, by the vapor deposition method, the sputtering method, or the like. Similarly, the cathode 3 can be formed by depositing the conductive material onto the ETL 15 by the vapor deposition method, the sputtering, or the like.

The HIL 11 is a layer having hole transport properties and promoting injection of holes from the anode 2 into the HTL 12. As a material of the HIL 11, for example, a hole transporting material such as a composite (PEDOT: PSS) of poly(3,4-ethylenedioxythiophene) (PEDOT) and polystyrene sulfonic acid (PSS) is used. For the formation of the HIL 11, any method such as, for example, a spin coating method or an inkjet method can be appropriately selected.

The HTL 12 is a layer having hole transport properties and transporting holes from the HIL 11 to the EML 13. As a material of the HTL 12, for example, a hole transporting material such as poly [(9,9-dioctylfluorenyl-2,7-diyl)-co-(4,4′-(N-4-sec-butylphenyl)) diphenylamine)] (TFB), poly [N,N′-bis(4-butylphenyl)-N,N′-bis(phenyl)-benzidine] (p-TPD), polyvinylcarbazole (PVK), NiO, WO₃, or MoO₃ is used. For the formation of the HTL 12, any method such as, for example, a spin coating method or an inkjet method can be appropriately selected.

As described above, the light-emitting element 1 is a QLED, and the EML 13 is a QD light-emitting layer including the QD 21 as a light-emitting material. The EML 13 includes the QD 21, the metal halide 22 (second metal halide) having solubility in water at 25° C. of less than 2.5 mg/100 g, and the metal halide 31 (first metal halide) having solubility in water at 25° C. of 2.5 mg/100 g or more. The EML 13 includes a nano-size QD 21 corresponding to an emission color as a light-emitting material.

In the EML 13, a hole transported from the anode 2 and an electron transported from the cathode 3 are rebonded, and an exciton generated by this emits light in a process of transitioning from a conduction band level to a valence band level of the QD 21.

The QD 21 is a dot having a particle maximum width of 100 nm or less. The QD 21 may be generally called a semiconductor nanoparticle because its composition is derived from a semiconductor material. The QD 21 may be generally called an inorganic nanoparticle because its composition is derived from an inorganic material. The QD 21 may be called a nanocrystal because its structure has a specific crystal structure, for example.

The shape of the QD 21 is not particularly limited as long as it is within a range satisfying the maximum width, and the shape thereof is not limited to a spherical three-dimensional shape (circular cross-sectional shape). The shape of the QD 21 may be, for example, a polygonal cross-sectional shape, a rod-shaped three-dimensional shape, a branch-shaped three-dimensional shape, or a three-dimensional shape having unevenness on the surface thereof, or a combination of them.

The QD 21 may include at least one metal element. Examples of the metal element included in the QD 21 include Cd, Zn, In, Sb, Al, Si, Ga, Pb, Ge, and Mg. The QD 21 may be a semiconductor material in which at least one metal element and a non-metal element such as S, Te, Se, N, P, and As are combined.

The QD 21 may be formed only of a core, and may be of a two-component core type, of a three-component core type, or of a four-component core type. As illustrated in FIG. 3, the QD 21 may have a core-shell structure including a core 21a and a shell 21b, and may be a core-shell type or a core-multi-shell type.

As illustrated in FIG. 3, when the QD 21 includes the shell 21b, the core 21a may be provided in a center part, and the shell 21b may be provided on a surface of the core 21a. The shell 21b desirably covers the entire core 21a, but it is not necessary for the shell 21b to completely cover the core 21a. The shell 21b may be formed on a part of the surface of the core 21a. The QD 21 can be said to have the core-shell structure if it is found that the shell 21b is formed on a part of the surface of the core 21a, or it is found that the shell 21b envelopes the core 21a, in an observation of a cross-section of the QD 21. Accordingly, it is sufficient to determine that the shell 21b covers the entire core 21a by an observation of a cross-section of the QD 21. Note that the cross-section observation can be performed by, for example, a scanning transmission electron microscope (STEM) or a transmission electron microscope (TEM).

The QD 21 may also include doped nanoparticles or include a compositionally graded structure. The shell 21b may be formed in a state of being solid-solved on the surface of the core 21a. In FIG. 3, a boundary between the core 21a and the shell 21b is indicated by a dotted line, and this indicates that the boundary between the core 21a and the shell 21b may be confirmed or need not be confirmed by analysis. The shell 21b may be formed in a plurality of layers.

The core 21a can be made of, for example, Si, Ge, CdSe, CdS, CdTe, InP, GaP, InN, ZnSe, ZnS, ZnTe, CdSeTe, GaInP, ZnSeTe, or the like. The shell 21b can be made of, for example, CdS, ZnS, CdSSe, CdTeSe, CdSTe, ZnSSe, ZnSTe, ZnTeSe, AlP, or the like. When the QD 21 has a core-shell structure, examples of the material of the QD 21 (combination of materials of the core 21a/the shell 21b) include ZnSe/ZnS, InP/ZnS, and CdSe/CdS.

An emission wavelength of the QD 21 can be changed in various ways depending on, for example, a particle size and composition thereof. The QD 21 is a QD that emits visible light, and the emission wavelength can be controlled from a blue wavelength region to a red wavelength region by appropriately adjusting the particle size and composition of the QD 21.

The metal halide 22 (second metal halide) is a metal halide having solubility in water at 25° C. of less than 2.5 mg/100 g as described above. Note that the metal halide 22 will be described later together with the metal halide 31 (first metal halide).

When no ligand is present on the surface of the QD 21 by performing ligand removal or the like as described above, the bulk physical properties of the QD 21 become apparent. When the surface of the QD 21 of ligandless (the surface of the core 21a or the shell 21b) is in direct contact with the carrier transporting material dispersion in this manner, a problem of wettability of the carrier transporting material dispersion to the EML 13 may occur. For example, in the QD 21 having only the core 21a or the core-shell structure in which a Zn atom exists on the surface of the QD 21, the Zn atom exposed on the surface can be a factor of deactivation of the exciton. Therefore, it is desirable that a ligand is coordinated to the surface of the QD 21.

Note that in the disclosure, “coordination” indicates that the ligand interacts with the QD 21 surface, and for example, indicates that the ligand is adsorbed to the QD 21 surface (in other words, the ligand modifies the QD 21 surface). Note that here, “adsorption” indicates that a concentration of the ligand is higher on the surface of the QD 21 than that in the surroundings. The adsorption may be chemical adsorption in which there is a chemical bond between the QD 21 and the ligand, physical adsorption, or electrostatic adsorption.

Accordingly, the ligand may be bonded or needs not necessarily be bonded by a coordinate bond, a covalent bond, an ionic bond, a hydrogen bond, or the like as long as interaction with the surface of the QD 21 is possible. The interaction may be interaction of, for example, coordinative bonding, covalent bonding, ionic bonding, or hydrogen bonding, or may be van der Waals interaction or other molecular interaction. As such, in the disclosure, a “ligand” refers to a molecule or ion that can interact with the surface of the QD 21. In the disclosure, if it can be confirmed that a molecule or an ion that can interact with the QD 21 and the surface of QD 21 exists in the EML 13, the molecule or the ion can be called a “ligand”. Note that in the disclosure, not only a molecule or an ion coordinated to the surface of the QD 21 but also a molecule or an ion that can be coordinated but is not coordinated is also called a “ligand”.

In a carrier injection type light-emitting element, the shorter the length of the ligand, the better. Therefore, in the present embodiment, a metal halide is used as a ligand (inorganic ligand). The metal halide has a shorter ligand length than an organic ligand generally used for stable dispersion, and can bring the QDs 21 close to each other. Therefore, the metal halide can improve carrier injection properties and suppress a decrease in luminous efficiency due to a defect on the surface of the QD 21 as compared with the organic ligand.

The metal halide 22 exists as an anion 22a and a cation 22b. Of the anion 22a and the cation 22b, a halogen that is the anion 22a is negatively charged, and thus is attracted to the positively charged surface of the QD 21 as a halogen ligand.

Similarly, the metal halide 31 exists as an anion 31a and a cation 31b. Of the anion 31a and the cation 31b, a halogen that is the anion 31a is negatively charged, and thus is attracted to the positively charged surface of the QD 21 as a halogen ligand.

For example, as illustrated in FIG. 2, the EML 13 may include the QD 21, the metal halide 22 in a state before being coordinated or in a state of being coordinated to the QD 21, and the metal halide 31 in a state before being coordinated or in a state of being coordinated to the QD 21. Here, the “state before being coordination” indicates a state in which an anion and a cation to be a counter ion are bonded. The “state before being coordination” indicates, for example, a state in which the anion 22a and the cation 22b are bonded or a state in which the anion 31a and the cation 31b are bonded. The “state of being coordinated” indicates a state in which a halogen that is the anion 22a or the anion 31a interacts with the surface of the QD 21 (e.g., a state in which a halogen is bonded to the surface of the QD 21 as a halogen ligand).

Examples of the anion 22a or the anion 31a include F⁻, Cl⁻, Br⁻, and I⁻. Examples of the cation 22b or the cation 31b include metal ions such as Li⁺, Na⁺, K⁺, Rb⁺, Cs⁺, Be²⁺, Mg²⁺, Ca²⁺, Sr²⁺, Ba²⁺, Zn²⁺, Al³⁺, Ga³⁺, In³⁺, Sn²⁺, and Pb²⁺. Note that a specific metal halide 22 and a specific metal halide 31 will be described later.

As illustrated in FIG. 4, the EML 13 according to the present embodiment may include an organic ligand 23 in addition to the QD 21, the metal halide 22, and the metal halide 31, and the organic ligand 23 may be coordinated to the surface of the QD 21.

The organic ligand 23 is an organic compound including at least one coordinating functional group that can be coordinated to the QD 21. Typical examples of the coordinating functional group include at least one type of functional group selected from the group consisting of an amino group, a phosphon group, a phosphine group, a phosphine oxide group, a carboxyl group, and a thiol group.

When the EML 13 further includes the organic ligand 23, the EML 13 may include, as the organic ligand 23, an organic compound in a state before being coordinated or in a state of being coordinated to the QD 21. Note that when the organic ligand 23 has, for example, a thiol (—SH) group as a coordinating functional group, the organic ligand 23 is coordinated to the QD 21 by sulfide (—S—) bonding with a hydrogen atom of the thiol group released. Therefore, here, the organic compound “in a state before being coordinated” refers to an organic compound in a state in which, for example, a hydrogen atom released by coordination is bonded.

Examples of the organic ligand 23 include amine compounds such as oleylamine and dodecylamine; phosphone compounds such as (12-phosphonododecyl) phosphonic acid or 11-mercaptoundecylphosphonic acid; phosphine compounds such as trioctylphosphine and tributylphosphine; phosphine oxide compounds such as trioctylphosphine oxide and tributylphosphine oxide; aliphatic compounds such as oleic acid and octanoic acid; and thiol compounds such as dodecanethiol and octanethiol.

However, in order to facilitate carrier injection, it is desirable that the proportion of the organic ligand 23 in the total amount of ligands is small, or that the EML 13 is organic ligandless not including or substantially not including the organic ligand 23. From the viewpoint of the effect of the halogen ligand, the weight ratio of the organic ligand 23 to the QD 21 in the EML 13 (the weight proportion of the organic ligand 23 to the weight of the QD 21) is desirably 30% or less, more desirably 20% or less, and particularly desirably 10% or less, depending on the type and size of the QD 21 and the molecular weight of the organic ligand 23. The weight ratio of the organic ligand 23 to the QD 21 in the EML 13 can be evaluated by differential thermal analysis (TG-DTA). The weight ratio of the organic ligand 23 to the QD 21 in the EML 13 measured by TG-DTA is about 30% when the EML 13 includes only the organic ligand 23 as a ligand. By substituting the organic ligand 23 with the metal halide 22, the weight ratio of the organic ligand 23 to be measured by TG-DTA can be reduced to 20% or less, for example. By performing organic ligand removal described later, the weight ratio of the organic ligand 23 to be measured by TG-DTA can be reduced to 10% or less.

In the disclosure, when an absorption spectrum derived from an organic ligand is confirmed by Fourier transform infrared spectroscopy (FT-IR) and it can be confirmed that “an absorption spectrum derived from an organic ligand cannot be detected by the FT-IR, that is, measurement intensity is equal to or less than noise”, “organic ligandless” is confirmed.

The number of molecules of the organic ligand 23 with respect to the number of metal atoms can be calculated by measuring the amount of the desorption component of the organic ligand 23 during heating by TG-DTA. Note that the number of molecules of the organic ligand 23 with respect to the number of metal atoms calculated from the size of the QD 21 in the EML 13 formed without performing removal of the organic ligand 23 is usually about 38%, and roughly 100% or more in a solution state.

As a ligand, an organic ligand is often coordinated to a synthetic or commercially obtained QD. A commercially available QD generally comes in a quantum dot dispersion (QD dispersion) including an organic ligand. The organic ligand is used as a dispersant to improve the dispersibility of the QD in a QD dispersion, and is also used to improve the surface stability and storage stability of the QD. For example, a wet method is used for synthesis of the QD, and particle size control of the QD is performed by coordinating an organic ligand to the surface of the QD. Therefore, the QD dispersion synthesized by the wet method includes the organic ligand used for the synthesis of the QD.

In the present embodiment, as described above, in the light-emitting layer formation (step S3), first, the EML 13 including the QD 21 and the metal halide 22 is formed.

Therefore, in order to form the EML 13 in which the metal halide 22 is coordinated to the surface of the QD 21 in the light-emitting layer formation (step S3), it is necessary to substitute the organic ligand included in the synthesized or commercially obtained QD dispersion with the metal halide 22. Note that, for example, an unsubstituted organic ligand included in the QD dispersion thus synthesized or commercially obtained may be coordinated to the surface of the QD 21 as the organic ligand 23. However, for various purposes such as improvement of dispersibility of the QD 21, an organic ligand different from the organic ligand included in the synthesized or commercially obtained QD dispersion may be used as the ligand. Therefore, the organic ligand 23 may be an organic compound different from the organic ligand included in the synthesized or commercially obtained QD dispersion.

In any case, in order to form the EML 13 in which the metal halide 22 is coordinated to the surface of the QD 21, at least some of the organic ligands 23 present on the surface of the QD 21 need to be substituted with the metal halide 22.

Therefore, the light-emitting layer formation (step S4) may include preparing the QD dispersion including the QD 21 and the organic ligand 23, and substituting the organic ligand 23 with the metal halide 22 before applying the QD dispersion or after applying the QD dispersion. By ligand-substituting the organic ligand 23 with the metal halide 22 in this manner, an EML including the QD 21 and the metal halide 22 can be formed as the EML 13.

Note that the type of a ligand included in the EML 13 can be identified by combining a plurality of analysis methods such as a matrix assisted laser desorption ionization (MALDI) method, a time-of-flight mass spectrometry (TOF-MS) method, a liquid chromatograph mass spectrometry (LC-MS/MS) method, a time-of-flight secondary ion mass spectrometry (TOF-SIMS) method, an inductively coupled plasma atomic emission spectrometry (ICP-AES) method, and a nuclear magnetic resonance (NMR) method.

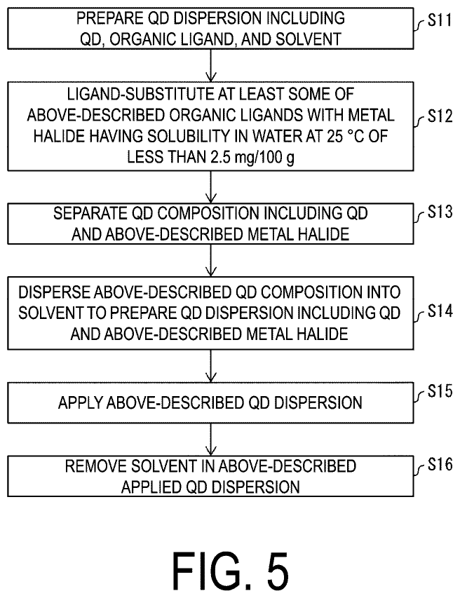

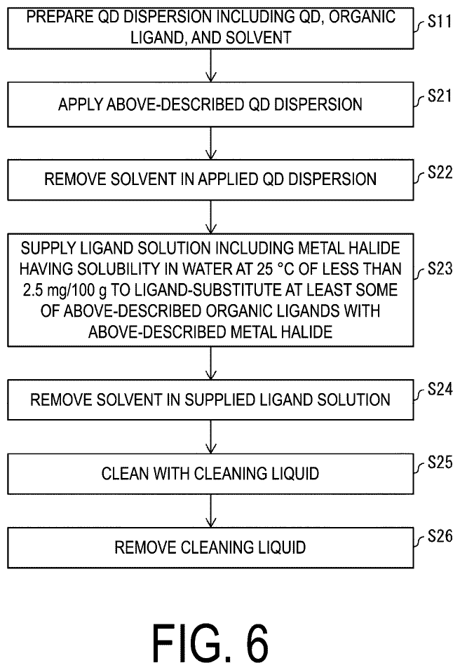

Hereinafter, the light-emitting layer formation (step S4) will be described more specifically with reference to FIGS. 5 and 6.

FIG. 5 is a flowchart showing an example of the light-emitting layer formation. Hereinafter, a case where the light-emitting layer formation includes preparing a QD dispersion including the QD 21 and the organic ligand 23 and substituting the organic ligand 23 with the metal halide 22 before applying the QD dispersion will be described.

In this case, in the light-emitting layer formation, first, as shown in FIG. 5, a QD dispersion (hereinafter, called a “first QD dispersion”) including the QD 21, the organic ligand 23, and a solvent (second solvent) is prepared (step S11, first QD dispersion preparation). Note that the first QD dispersion preparation may be QD synthesis or redispersing the QD obtained in the QD synthesis in the solvent. Hereinafter, a case where the first QD dispersion is prepared using the QD 21 and the organic ligand 23 included in a QD dispersion (hereinafter, called an “initial QD dispersion”) including the QD 21 and the organic ligand 23 synthesized or commercially obtained will be described as an example.

In the first QD dispersion preparation, for example, first, the QD 21 in which the organic ligand 23 is coordinated to the surface is separated from the initial QD dispersion. In separation of the QD 21, for example, first, the initial QD dispersion is collected in a reaction vessel such as a centrifuge tube. The initial QD dispersion includes the QD 21, the organic ligand 23, and a solvent. As the solvent, a nonpolar solvent is used. Examples of the nonpolar solvent include cyclohexane, toluene, hexane, octane, and chlorobenzene.

Subsequently, an excessive amount of a poor solvent is dropped to the initial QD dispersion in the reaction vessel to precipitate the QD 21 in which the organic ligand 23 is coordinated included in the initial QD dispersion. As the poor solvent, a solvent in which the QD 21 is not dispersed, such as ethanol, is used.

Subsequently, centrifugation is performed and a supernatant is removed. Subsequently, the QD 21 that is precipitated is cleaned, and the QD 21 that is precipitated (i.e., the QD 21 in which the organic ligand 23 is coordinated) is separated. Note that the cleaning of the QD 21 is performed by repeating a plurality of times the operation of adding a nonpolar solvent as a solvent again to the 21 that is precipitated, redispersing the QD 21, then adding a poor solvent again to centrifuge, and removing the supernatant. This can remove at least some of the excessive organic ligands 23 not coordinated to the QD 21 included in the initial QD dispersion.

Subsequently, the nonpolar solvent is added again as a solvent (second solvent) to the QD 21 in the separated reaction vessel to redisperse the QD 21 in the nonpolar solvent. Due to this, the first QD dispersion including the QD 21, the organic ligand 23 coordinated to the QD 21, and the nonpolar solvent as the second solvent is prepared.

Subsequently, a ligand solution including the metal halide 22 and a trace amount of a polar solvent as a solvent (solvent of the ligand solution) is added to the first QD dispersion in the reaction vessel and stirred. For the ligand solution, as described above, a polar solvent in which the metal halide 22 is easily dissolved was used as the solvent. The nonpolar solvent in which the QD 21 is dispersed (e.g., cyclohexane, toluene, and the like, as described above) and the polar solvent in which the metal halide 22 is dissolved (e.g., ethanol) are miscible as long as they are within an appropriate range. Thereafter, the reaction liquid in the reaction vessel is left to stand for a predetermined time. Due to this, at least some the organic ligands 23 included in the first QD dispersion are ligand-substituted with the metal halide 22 (step S12, ligand substitution).

Note that the conditions used for ligand substitution, such as the concentration of the metal halide 22 in the ligand solution, the addition amount of the ligand solution, and the time required for stirring and leaving to stand, are not particularly limited. These conditions may be appropriately set in accordance with the material or the like to be used, for example, such that the ratio of each ligand in the EML 13 to be finally formed becomes a desired ratio.

Subsequently, an excessive amount of the poor solvent is again dropped into the reaction vessel. Thereafter, centrifugation is performed and a supernatant is removed. This removes at least some of the excessive metal halides 22 not coordinated to the QD 21 included in the supernatant and the solvent in the reaction vessel, and separates a QD composition including the QD 21 and the metal halide 22 present on the surface of the QD 21 (step S13, QD composition separation).

Thereafter, a nonpolar solvent as a solvent (solvent for a second QD dispersion described later) is added into the reaction vessel, and the QD composition is dispersed in the nonpolar solvent. This prepares a QD dispersion (hereinafter, called a “second QD dispersion”) including at least the QD 21, the metal halide 22, and the nonpolar solvent (step S14, second QD dispersion preparation).

Note that the solvent of the first QD dispersion needs to be miscible with the polar solvent in which the metal halide 22 is dissolved (the QD 21 is dispersed without precipitating even if a trace amount of polar solvent is dropped), but the solvent used for the second QD dispersion does not need to be so.

Subsequently, the second QD dispersion is applied onto the HTL 12 to form a coating film of the second QD dispersion (step S15, second QD dispersion application). For the application of the second QD dispersion, any method such as a bar coating method, a spin coating method, or an inkjet method can be appropriately selected. Subsequently, the coating film is heated and dried or the like to remove the solvent included in the applied second QD dispersion (step S16, solvent removal). This can form the EML 13 illustrated in FIG. 2 including the QD 21 and the metal halide 22 present on the surface of the QD 21.

Note that as described above, the EML 13 may further include the organic ligand 23. However, as described above, in order to facilitate carrier injection, it is desirable that the proportion of the organic ligand 23 in the total amount of ligands is small, or that the EML 13 is organic ligandless not including or substantially not including the organic ligand 23. Therefore, if the second QD dispersion includes the organic ligand 23, the solvent in step S15 is removed, a thin film including the QD composition is formed, and then additional ligand substitution may be further performed.

FIG. 6 is a flowchart showing another example of the light-emitting layer formation (step S4). Hereinafter, a case where the light-emitting layer formation includes preparing a QD dispersion including the QD 21 and the organic ligand 23 and substituting the organic ligand 23 with the metal halide 22 after applying the QD dispersion will be described.

In this case, in the light-emitting layer formation, first, as shown in FIG. 6, step S11 similar to step S11 shown in FIG. 5 is performed. This prepares the first QD dispersion including the QD 21, the organic ligand 23 coordinated to the QD 21, and the nonpolar solvent as the second solvent (step S11, first QD dispersion preparation).

Subsequently, the first QD dispersion is applied onto the HTL 12 to form a coating film of the first QD dispersion (step S21, first QD dispersion application). For the application of the first QD dispersion, any method such as a bar coating method, a spin coating method, or an inkjet method can be appropriately selected. Subsequently, the coating film is heated and dried or the like to once remove the solvent included in the applied first QD dispersion (step S22, solvent removal). This forms the EML 13 including the QD 21 and the organic ligand 23 coordinated to the QD 21.

Subsequently, the EML 13 including the QD 21 and the organic ligand 23 is supplied with a ligand solution including the metal halide 22 and a polar solvent as a solvent (solvent of the ligand solution) to bring the ligand solution and the EML 13 into contact with each other. For the supply of the ligand solution, for example, an inkjet method may be used, or a mist spraying device may be used. In order to bring the ligand solution into uniform contact with the EML 13, a sufficient amount of the ligand solution may be supplied by dropping to the EML 13 or the like, left to stand for a predetermined time, and then the ligand solution may be applied onto the EML 13 by, for example, spin coating or the like. Examples of the polar solvent include alcohols such as ethanol.

By bringing the ligand solution and the EML 13 into contact with each other in this manner, at least some the organic ligands 23 included in the EML 13 are ligand-substituted with the metal halide 22 (step S23, ligand substitution).

Note that also in this case, the conditions used for ligand substitution, such as the concentration of the metal halide 22 in the ligand solution, the addition amount of the ligand solution, and the time required for ligand substitution, are not particularly limited. Also in this case, these conditions may be appropriately set in accordance with the material or the like to be used, for example, such that the ratio of each ligand in the EML 13 to be finally formed becomes a desired ratio.

The ligand solution may be supplied to the EML 13 by immersing, into the ligand solution, the substrate on which the EML 13 including the QD 21 and the organic ligand 23 is formed, in place of supplying the ligand solution by spin coating or the like.

Subsequently, the EML 13 after the supply of the ligand solution is heated and dried or the like to remove the solvent included in the supplied ligand solution (step S24, solvent removal).

Subsequently, the EML 13 is supplied with a sufficient amount of cleaning liquid, and the EML 13 is cleaned with the cleaning liquid. This removes at least some of the excess metal halides 22 not coordinated to the QD 21 (step S25, cleaning).

Thereafter, the EML 13 is heated and dried or the like to remove the solvent included in the EML 13, that is, the cleaning liquid (step S26, cleaning liquid removal). As the cleaning liquid, for example, a polar solvent such as ethanol is used. This can form the EML 13 illustrated in FIG. 2 including the QD 21 and the metal halide 22 present on the surface of the QD 21.

Note that also in this case, as described above, the EML 13 may further include the organic ligand 23. However, also in this case, as described above, in order to facilitate carrier injection, it is desirable that the proportion of the organic ligand 23 in the total amount of ligands is small, or that the EML 13 is organic ligandless not including or substantially not including the organic ligand 23.

In the light-emitting layer formation shown in FIG. 5, when additional ligand substitution is further performed after step S15 as described above, processes similar to steps S23 to S26 may be performed after step S15. By performing an additional ligand substitution process in this manner, the ligand substitution amount can be increased, and the organic ligand 23 can be removed. However, the above exemplification is merely an example, and the EML 13 of organic ligandless including no or substantially no organic ligand 23 can be formed by appropriately adjusting ligand substitution conditions in step S12 (ligand substitution).

As the metal halide 22 used for the ligand solution, as described above, a metal halide having solubility in water at 25° C. of less than 2.5 mg/100 g is used. Examples of the metal halide 22 having solubility in water at 25° C. of less than 2.5 mg/100 g in this manner include at least one type selected from the group consisting of CaF₂, ZnF₂, and GaF₃.

Among these exemplified metal halides 22, ZnF₂ composed of F, which is a halogen having a small ionic radius, and a cation of the same type as Zn on the surface of the QD 21, for example, the surface of the shell 21b is suitable for surface modification of the QD 21.

However, some metal halides such as ZnF₂, specifically, the metal halides 22 having solubility in water at 25° C. of less than 2.5 mg/100 g have very low solubility in polar solvents such as alcohols used for formation of the CTL such as the ETL 15. When the QD 21 has, for example, Zn—F bond on the surface as in the case of using ZnF₂ as a ligand, the surface tension of the EML 13 surface including the QD 21 is smaller than the surface tension of the solvent (first solvent) used for formation of the CTL layered on the EML 13. Therefore, as described above, the EML 13 including the QD 21 ligand-substituted with the metal halide 22 such as ZnF₂ has poor wettability of the carrier transporting material dispersion used for formation of the CTL layered on the EML 13.

Therefore, when such the metal halide 22 is present on the surface of the EML 13 by applying a ligand solution including, for example, the metal halide 22 or the like as described above for surface modification of the QD 21, the carrier transporting material dispersion used for formation of the CTL to be layered on the EML 13 is repelled by the metal halide 22. As a result, it becomes difficult to uniformly layer the carrier transporting material 41 on the EML 13, and the layer thickness of the CTL to be layered on the EML 13 becomes non-uniform. Such a decrease in the layer thickness uniformity of the CTL leads to non-uniform light emission and deterioration of light-emission characteristics of the light-emitting element 1 to be obtained. As a result, element characteristics and reliability of the light-emitting element 1 to be obtained are deteriorated.

Therefore, in the present embodiment, as described above, in the intermediate layer formation (step S5), the IL 14 including a metal halide 31 (first metal halide) having solubility in water at 25° C. of 2.5 mg/100 g or more is formed on the EML 13. Then, in the electron transport layer formation (step S6), the ETL 15 is formed as a CTL on the IL 14, for example, as described above. This improves the wettability of the carrier transporting material dispersion to a base.

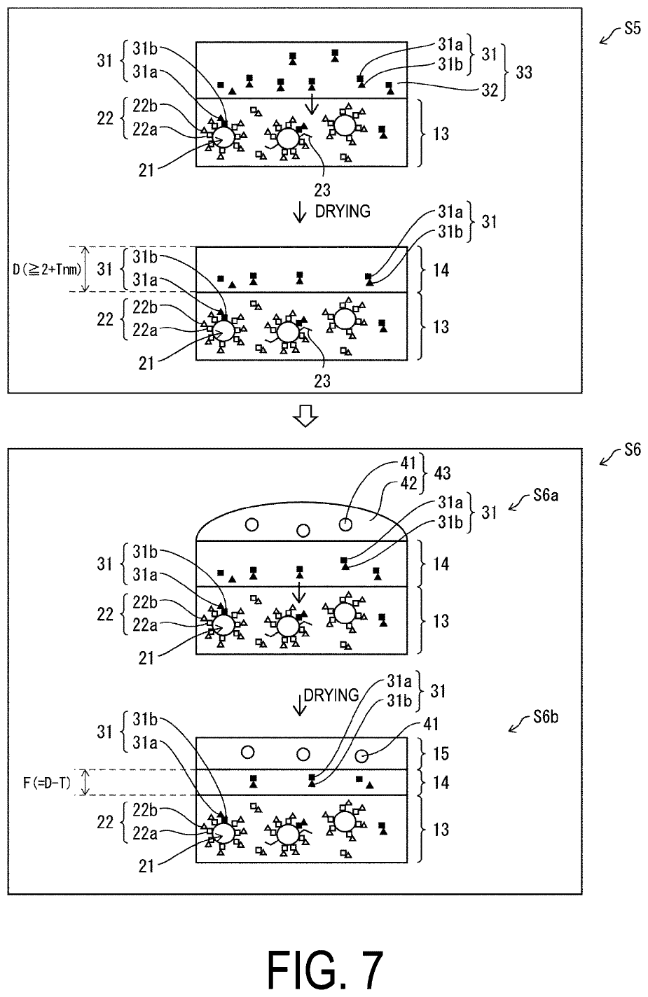

FIG. 7 is a cross-sectional view illustrating a schematic configuration of a main part in the intermediate layer formation (step S5) and the electron transport layer formation (step S6) shown in FIG. 1.

As illustrated in FIGS. 2 and 7, the IL 14 is a layer including the metal halide 31 and located between the EML 13 and the CTL (between the EML 13 and the ETL 15 in the examples illustrated in FIGS. 2 and 7).

The ETL 15 is a CTL including an electron transporting material and having an electron transporting function of increasing electron transporting efficiency to the EML 13. Examples of the electron transporting material include metal oxides such as ZnO, SnO, and TiO₂.

As illustrated in FIG. 7, a carrier transporting material dispersion 43 used for formation of the ETL 15 includes the carrier transporting material 41 and a solvent 42 (first solvent). As the solvent 42 used in the carrier transporting material dispersion 43, for example, a protic polar solvent such as alcohol is used. The metal halide 31 having solubility in water at 25° C. of 2.5 mg/100 g or more is dissolved in the protic polar solvent such as alcohol used in the carrier transporting material dispersion 43 in this manner.

However, the solubility of the metal halide varies depending on the solvent used. Nevertheless, it is not easy and it is very troublesome to examine the solubility of the metal halide every time the solvent is changed. Therefore, in the present embodiment, the solubility of the metal halide is defined by the solubility in water, which is the most common polar solvent, in which the solubility of the metal halide is greater than that of alcohol, and the solubility tendency is similar to that of a protic polar solvent.

In the intermediate layer formation (step S5), the EML 13 including the metal halide 22 substituted through the ligand substitution described above is applied with a metal halide-including liquid 33 including the metal halide 31 and a polar solvent as the solvent 32 (solvent for intermediate layer formation, third solvent) to form a coating film including the metal halide 31. Thereafter, the coating film is heated and dried or the like, and the solvent 32 included in the applied metal halide-including liquid 33 is removed. Due to this, some of the ligands (the organic ligands 23 when the EML 13 includes the metal halide 22 and the organic ligand 23) on the surface of the QD 21 in the EML 13 is substituted with the metal halide 31, and a metal halide layer including the metal halide 31 is formed as the IL 14 on the EML 13.

The application of the metal halide-including liquid 33 may be performed by immersing the substrate on which the EML 13 is formed into the metal halide-including liquid 33, or may be performed by applying the metal halide-including liquid 33 on the EML 13 by a spin coating method, an inkjet method, or the like. In this case, in order to bring the metal halide-including liquid 33 into uniform contact with the EML 13, a sufficient amount of the metal halide-including liquid 33 may be supplied by dropping to the EML 13 or the like, left to stand for a predetermined time, and then the metal halide-including liquid 33 may be applied onto the EML 13 by, for example, spin coating or the like. Also in this case, examples of the polar solvent include alcohols such as ethanol.

Examples of the metal halide 31 include at least one type selected from the group consisting of, for example, LiF, NaF, KF, RbF, CsF, BeF₂, MgF₂, SrF₂, BaF₂, AlF₃, InF₃, PbF₂, LiCl, NaCl, KCl, RbCl, CsCl, BeCl₂, MgCl₂, CaCl₂, SrCl₂, BaCl₂, AlCl₃, GaCl₃, LiBr, NaBr, KBr, RbBr, CsBr, BeBr₂, MgBr₂, CaBr₂, SrBr₂, BaBr₂, AlBr₃, SnBr₂, LiI, NaI, KI, RbI, CsI, BeI₂, MgI₂, CaI₂, and SrI₂.

According to the present embodiment, when the IL 14 is formed on the EML 13, as illustrated in FIG. 7, the ETL 15 can be formed by the carrier transporting material dispersion 43 while dissolving a part of the IL 14 by the application of the carrier transporting material dispersion 43.

For example, when the IL 14 including BaF₂ or ZnCl₂ as the metal halide 31 is formed on the EML 13 including the QD 21 and ZnF₂ as the metal halide 22, the ETL 15 is formed while dissolving some of these metal halides 31 (BaF₂ or ZnCl₂). This improves the wettability of the carrier transporting material dispersion 43 to the base.

Phenomena such as application of the carrier transporting material dispersion 43 onto the base, drying, and surface aggregation of nanoparticles are involved with physical properties such as interfacial tension between a solid and a liquid, solubility, and solid surface potential. Therefore, the wettability of the carrier transporting material dispersion 43 with respect to the base is improved by improving the wettability of the ligand present on the surface of the QD 21 and the carrier transporting material dispersion 43 based on these physical properties.

For example, as described above, the metal halide 31 having solubility in water at 25° C. of 2.5 mg/100 g or more has good wettability of the carrier transporting material dispersion 43. Therefore, some of the organic ligands in the initial QD dispersion are substituted with, for example, ZnCl₂, which is such a metal halide, to form the EML 13, and then the EML 13 is repeatedly applied with an alcohol solution of ZnCl₂ and cleaned to perform additional ligand substitution. Due to this, when the surface of the QD 21 is composed of ZnCl₂, the wettability of the carrier transporting material dispersion 43 with respect to the EML 13 does not deteriorate.

Therefore, it is also conceivable to substitute some of the halogen ligands on the QD 21 surface with halogen ligands suitable for alcohol application, for example, without forming the IL 14 between the EML 13 and the CTL. For example, a QD thin film in which the organic ligand 23 is ligand-substituted with a fluoride ligand is applied with an ethanol solution of a metal halide having high solubility. Alternatively, the substrate on which the QD thin film is formed is immersed in the ethanol solution of such a metal halide to perform cleaning. This allows some of the fluoride ligands on the surface of the QD 21 to be ligand-substituted with halogen ligands suitable for alcohol application, such as chloride ligands. Also in this case, the wettability of the carrier transporting material dispersion 43 can be improved.

However, it is difficult to completely substitute, for example, a fluoride ligand on the QD 21 surface with a chloride ligand. As described above, the metal halide 31 such as ZnCl₂ is dissolved in the carrier transporting material dispersion 43.

Therefore, in the present embodiment, the IL 14 is formed on the EML 13. According to the present embodiment, by forming the IL 14 that can improve the wettability of the carrier transporting material dispersion 43 on the EML 13 in this manner, the wettability of the carrier transporting material dispersion 43 can be further improved, and the light-emitting element 1 having good uniformity of the layer thickness and excellent light-emission characteristics and reliability can be provided.

As described above, the IL 14 is particularly effective when the EML 13 is provided with a CTL such as the ETL 15 in the process.

Note that for formation of the IL 14, it is necessary to select the metal halide 31 corresponding to the metal halide 22 on the QD 21 surface in the EML 13 serving as a base. When, for example, ZnF₂ is used as the metal halide 22, for example, ZnCl₂ may be used as the metal halide 31 as described above. However, from the viewpoint of ligand substitution on the QD 21 surface and the formation of the IL 14, it is desirable to use a metal halide having the same halogen for the metal halide 22 and the metal halide 31.

The metal halide 31 includes the anion 31a and the cation 31b. When, for example, ZnF₂ is used as the metal halide 22, a metal halide including a fluoride ligand as the anion 31a, such as CsF or BaF₂, is desirably selected as the metal halide 31.

As described above, when the IL 14 including ZnCl₂ as the metal halide 31 is formed on the EML 13 including the QD 21 and ZnF₂ as the metal halide 22, the ETL 15 is formed while dissolving a part of ZnCl₂.

The metal halide has a size allowing to pass through a gap between the QDs 21 in the EML 13. Therefore, as illustrated in FIG. 7, when the IL 14 is applied with the carrier transporting material dispersion 43, a part of the IL 14 is dissolved as described above by the solvent 42 included in the carrier transporting material dispersion 43, and the metal halide 31 included in the IL 14 enters the EML 13.

Therefore, as described above, when the EML 13 including the metal halide 22 is formed, the EML 13 further includes the metal halide 31 in addition to the metal halide 22. Therefore, in this case, both the anion 22a and the anion 31a exist as ligands on the surface of the QD 21. Therefore, when ZnCl₂ is used as the metal halide 31 in a case where the metal halide 22 is ZnF₂ and ZnCl₂, two types of halogens, F and Cl, are present in the EML 13 after application of the carrier transporting material dispersion.

On the other hand, as described above, by using a metal halide having the same halogen for the metal halide 22 and the metal halide 31, even if the metal halide 31 included in the metal halide-including liquid 33 used for formation of the IL 14 enters the EML 13, the type of halide ions included in the EML 13 does not increase. Therefore, by using a metal halide having the same halogen species for the EML 13 and the IL 14, the influence on the QD 21 is small, and the decrease of the light-emission characteristics can be suppressed.

Note that since the metal halide 31 is composed of an ionic crystal, the IL 14 formed by drying the solution in which the metal halide 31 is dissolved becomes a crystalline thin film. Therefore, the gap present in the IL 14 is only a region of a crystal grain boundary and is 1 nm or less. Therefore, there is almost no gap in the IL 14. Therefore, the carrier transporting material 41 does not pass through the IL 14.

In order to improve the wettability of the carrier transporting material dispersion, it is preferable to dissolve the IL 14 by 2 nm or more. The metal halide 31 having solubility in water at 25° C. of 2.5 mg/100 g or more has a high solubility in a polar solvent such as water, and is dissolved by 2 nm or more by application of the carrier transporting material dispersion. Therefore, in the present embodiment, where the layer thickness of the IL 14 dissolved by the solvent 42 included in the carrier transporting material dispersion 43 is Tnm, it is preferable to form the IL 14 having a layer thickness D of 2+Tnm or more as illustrated in FIG. 7 in the intermediate layer formation.

In the present embodiment, in the carrier transporting material dispersion application (step S6a), the ETL 15 is formed while dissolving a part of the IL 14 by the solvent 42 included in the carrier transporting material dispersion 43. In the carrier transporting material dispersion application, as described above, the IL 14 is dissolved by 2 nm or more by the solvent 42.

On the other hand, where the layer thickness of the IL 14 in the light-emitting element 1 finally formed is F, the layer thickness F of the IL 14 is preferably 2 nm or more from the viewpoint of suppressing tunneling. Therefore, in the carrier transporting material dispersion application, the IL 14 is dissolved by the solvent 42 by 2 nm or more, and in the intermediate layer formation, the IL 14 having a layer thickness of 2+Tnm (T>2) or more is formed, whereby the wettability of the carrier transporting material dispersion 43 can be sufficiently improved, and carrier injection due to tunneling can be suppressed.

Note that in the present embodiment, the layer thickness of the IL 14 after the electron transport layer formation (step S6) is the layer thickness F of the IL 14 in the light-emitting element 1. Therefore, it is preferable that D−T=F, and T and F are each 2 nm or more (i.e., T≥2 nm and F≥2 nm). Therefore, in the intermediate layer formation, it is preferable to form the IL 14 having the layer thickness D of 4 nm or more.

In the present embodiment, the metal halide 22 may have solubility in water at 25° C. of 2.5 mg/100 g or more as described above. However, if the solubility of the metal halide 31 is too high, the IL 14 is completely dissolved when the carrier transporting material dispersion 43 is applied, and the metal halide 22 having a low solubility in the EML 13 is in direct contact with the carrier transporting material dispersion 43, whereby a problem of wettability of the carrier transporting material dispersion 43 may occur.

Therefore, in order not to cause the above problem, it is desirable to form the IL 14 with a thickness (preferably, the thickness such that F≥2 nm as described above) at which the IL 14 is not completely dissolved by the carrier transporting material dispersion 43 in the intermediate layer formation. Therefore, it is desirable to form the IL 14 thicker as the solubility of the metal halide 31 is higher. Alternatively, it is desirable to use a metal halide having the above solubility (i.e., solubility in water at 25° C.) of 10,000 mg (=10 g)/100 g or less as the metal halide 31. The solubility is solubility such that the IL 14 can be completely dissolved by about 5 μm when the IL 14 is left to completely dissolve in water at 25° C. Therefore, the metal halide 31 may be a metal halide having solubility in water at 25° C. of 2.5 mg/100 g or more and 10,000 mg (=10 g)/100 g or less.

Thus, according to the present embodiment, by selecting the material of the metal halide 31 and adjusting the thickness of the IL 14, the excess of electrons can be suppressed, the carrier balance can be improved, and the luminous efficiency of the light-emitting element 1 can be improved.

However, the present embodiment is not limited to this. In place of selecting the material of the metal halide 31 and adjusting the thickness of the IL 14 as described above, the dissolution of the IL 14 may be controlled by reducing the contact time between the IL 14 and the carrier transporting material dispersion 43 by, for example, shortening the dropping time (supply time) of the carrier transporting material dispersion 43 during spinning in the spin coating method.

As described above, the carrier transporting material dispersion 43 includes the carrier transporting material 41 and the solvent 42. The carrier transporting material 41 is desirably a metal oxide as described above, and the carrier transporting material dispersion 43 preferably has an isoelectric point of pH7 or more. Note that the metal oxide is used as a metal oxide nanoparticle.

The isoelectric point indicates pH of a solution in which the zeta potential (charge) of the particle surface is 0. For measurement of the isoelectric point, light scattering during electrophoresis (laser Doppler method) is widely used, and an electric field is applied to nanoparticles such as QD or ETL particles dispersed in a solution, and the zeta potential is calculated from the electrophoresis speed in accordance with the charge of the particles. The isoelectric point is measured by varying the pH of the solution at this time.

Many of the metal oxide nanoparticles in the carrier transporting material dispersion 43 including an alcohol as a main solvent are positively charged at a surface potential due to a surface terminal group thereof. In general, the surface of a metal oxide nanoparticle is covered with a hydroxyl group (—OH). In the metal oxide nanoparticle having an isoelectric point higher than pH7, the hydroxyl group (surface hydroxyl group) present on the surface of the metal oxide nanoparticle is M⁺ or M-OH₂⁺ under an electrically neutral condition (pH =7), and the particle surface is charged to + (plus). For this reason, the isoelectric point of most of the metal oxides except SiO₂ is greater than pH7, and the surface of the metal oxide tends to be positively charged.

Since the surface of the QD 21 is in a state in which, for example, Zn atoms are exposed and S atoms are insufficient, the surface of the QD 21 has a polarity of + as the polarity. Thus, the QD 21 and metal oxide nanoparticles electrostatically repel each other in most combinations because the surfaces are both positively charged. For this reason, it is difficult to regularly array the metal oxide nanoparticles on the QD 21.

However, according to the present embodiment, as described above, by inserting the metal halide 22 and the metal halide 31 between the QD 21 and the metal oxide nanoparticles to spatially separate the QD 21 and the metal oxide nanoparticles, the influence of the surface potential can be reduced. As a result, electrostatic repulsion between the QD 21 and the metal oxide nanoparticles can be suppressed, and the metal oxide nanoparticles can be regularly arrayed. Therefore, the uniformity of the layer thickness of the ETL 15 can be improved.

In general, in the QLED, the electron transporting material is greater in mobility than the hole transporting material. Therefore, in the QLED, electrons are often excessive in the EML. Therefore, when the IL 14 is formed between the EML 13 and the ETL 15 as described above, the IL 14 is preferably a wide band gap.

Specifically, when the QD 21 includes the core 21a and the shell 21b as described above, each of the band gap of metal halide 22 and the band gap of metal halide 31 is preferably greater than the band gap of the shell 21b. By making the band gaps of the metal halide 22 and the metal halide 31 greater than the band gap of the shell 21b in this manner, the carrier injected from the CTL into the EML 13 can be confined in the QD 21.

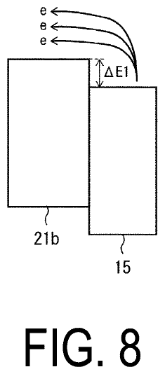

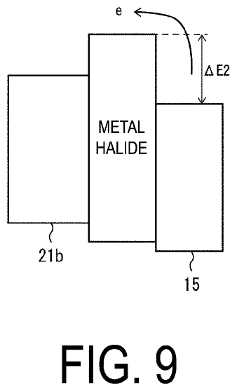

FIG. 8 is an energy band diagram for explaining an electron injection barrier in a case where a metal halide is not present between the shell 21b of the QD 21 and the ETL 15. FIG. 9 is an energy band diagram for explaining an electron injection barrier in a case where a metal halide is present between the shell 21b of the QD 21 and the ETL 15.

In the carrier injection type light-emitting element, when no metal halide is present between the shell 21b of the QD 21 and the ETL 15, the height of the electron injection barrier when electrons are injected from the ETL 15 into the QD 21 is indicated by an absolute value ΔE1 of a difference in energy level between the lower end (CBM) of the conduction band of the ETL 15 and the lower end (CBM) of the conduction band of the shell 21b as illustrated in FIG. 8. On the other hand, when a metal halide having a band gap greater than the band gap of the shell 21b is present between the shell 21b of the QD 21 and the ETL 15, the height of the electron injection barrier when electrons are injected into the QD 21 from the metal halide is ΔE2 as illustrated in FIG. 9, which is greater than ΔE1.

Therefore, by making the band gap of the metal halide between the shell 21b of the QD 21 and the ETL 15 greater than the band gap of the shell 21b in this manner, as illustrated in FIG. 8, electron injection from the ETL 15 to the EML 13 can be suppressed as compared with the case illustrated in FIG. 7.

Note that in the present embodiment, the metal halide between the shell 21b of the QD 21 and the ETL 15 is the metal halide 22 and the metal halide 31. Therefore, according to the present embodiment, by making the band gaps of the metal halide 22 and the metal halide 31 greater than the band gap of the shell 21b, electron injection from the ETL 15 to the EML 13 can be suppressed. As a result, the carrier balance can be improved, and the luminous efficiency of the light-emitting element 1 can be improved.

The band gaps of the metal halide 22 and the metal halide 31 may be greater than the band gap of the shell 21b as described above, and specific values thereof are not particularly limited. However, as a suitable value of the band gaps of the metal halide 22 and the metal halide 31, for example, the band gap is preferably wider than 3.4 eV, which is the band gap value of ZnS used for the shell 21b, for carrier injection.

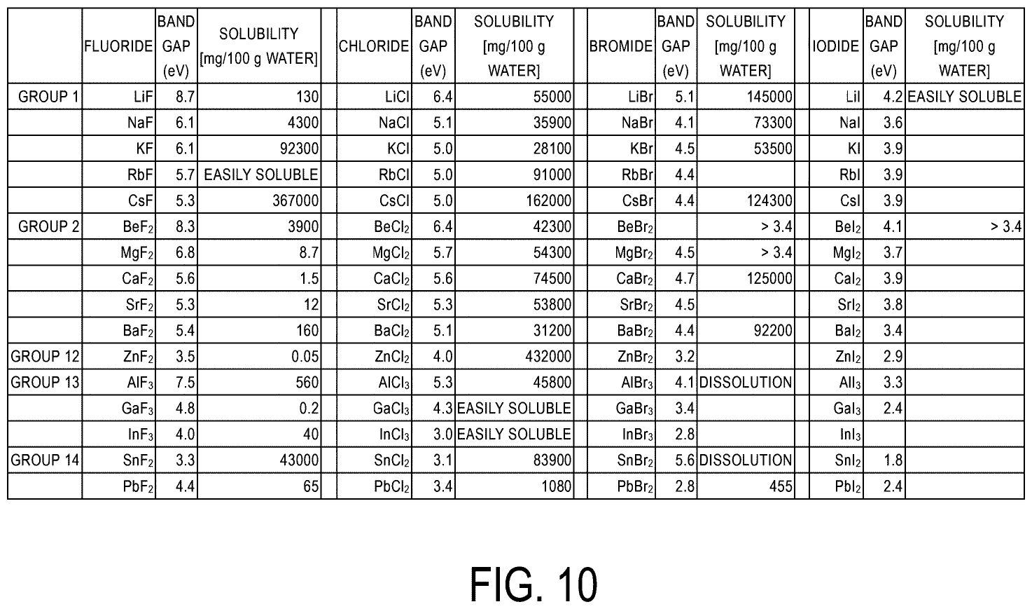

FIG. 10 collectively shows the band gaps and solubility of the main metal halides in water at 25° C.

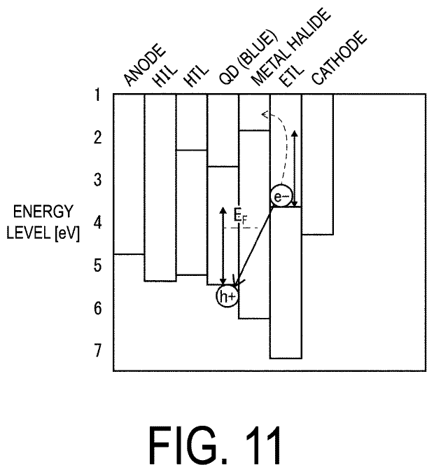

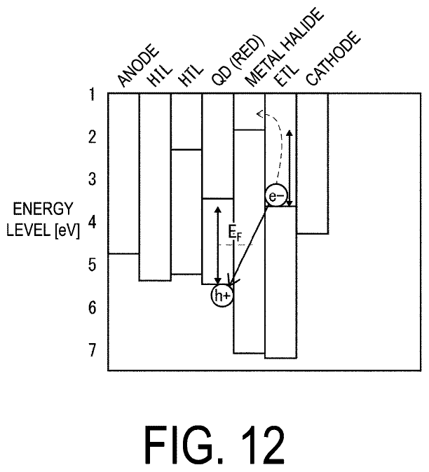

FIG. 11 is a view illustrating, as an example, the energy level of each layer of a light-emitting element in which a blue QD emitting blue light is used as the QD 21 and the band gap of the metal halide is about 4.4 eV (strictly, 4.4 eV or more). FIG. 12 is a view illustrating an energy level of each layer of a light-emitting element in which a red QD emitting red light is used as the QD 21 and the band gap of the metal halide is about 5.2 eV (strictly, 5.2 eV or more).

Note that in FIGS. 11 and 12, the heights of Fermi levels E_{F} of the metal halide and the QD 21 are in line with each other for comparing the energy levels. As illustrated in FIG. 11 and FIG. 12, in the red QD and the blue QD, the upper end of the valence band (VBM) is almost the same, and there are many reports of a tendency of band gap expansion due to a decrease in CBM of the red QD as compared with the blue QD due to a great effective mass difference of holes/electrons.

In order to efficiently perform carrier injection, it is preferable that the VBM of the ETL is deeper than the VBM of the metal halide in order to prevent carrier leakage from the QD layer (EML 13).

From the viewpoint of the band gap, for carrier injection, as described above, the band gap of the metal halide is preferably greater than the band gap of the shell 21b, for example, the band gap of ZnS as described above. However, when the band gap of the metal halide is too great, non-luminescent rebond of holes (h⁺) and electrons (e⁻) in a region other than the QD 21 easily occurs, and the luminous efficiency decreases. Therefore, when the band gap of the metal halide that does not cause non-luminescent rebond is calculated based on the energy levels of the ETL 15 and the QD 21, the band gap of the metal halide is preferably less than 5.2 eV, for example.

The light-emitting element 1 manufactured by the manufacturing method for a light-emitting element according to the present embodiment includes the EML 13 including the QD 21, the metal halide 22 (second metal halide), and the metal halide 31 (first metal halide) as described above, and has a configuration in which the IL 14 including the metal halide 31 and the ETL 15 including the carrier transporting material 41 as the CTL including the carrier transporting material are provided adjacent to each other in this order from the EML 13 side.

According to the present embodiment, since the IL 14 including the metal halide 31 and the ETL 15 including the carrier transporting material 41 are provided adjacent to each other in this order from the EML 13 side, the wettability of the coating liquid (i.e., the carrier transporting material dispersion 43) including the carrier transporting material 41 with respect to the EML 13 at the time of forming the ETL 15 can be improved. As a result, the light-emitting element 1 having good uniformity of the layer thickness and excellent light-emission characteristics and reliability can be provided.

### First Modified Example

In the present embodiment, as shown in FIG. 1, a case where the light-emitting element 1 has a conventional structure in which the anode 2 is a lower layer electrode has been described as an example. However, as described above, the light-emitting element 1 may have an inverted structure in which the cathode 3 is a lower layer electrode. The CTL formed on the IL 14 is not limited to the ETL, and may be the HTL.

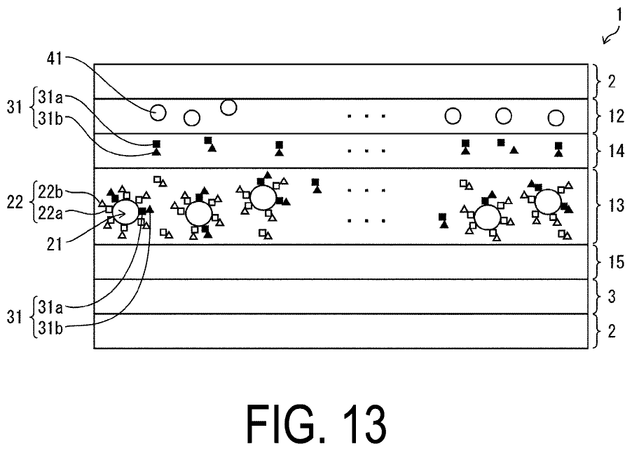

FIG. 13 is a cross-sectional view illustrating an example of a schematic configuration of the light-emitting element 1 according to the present modified example.

The light-emitting element 1 illustrated in FIG. 13 has an inverted structure in which the cathode 3 is a lower layer electrode and the anode 2 is an upper layer electrode, and as an example, has a configuration in which the cathode 3, the ETL 15, the EML 13, the HTL 12, and the anode 2 are provided in this order from the lower layer side (e.g., a support body side not illustrated such as a substrate). Note that although illustration and description are omitted, also in the present modified example, the light-emitting element 1 may include a function layer not illustrated between the anode 2 and the cathode 3.

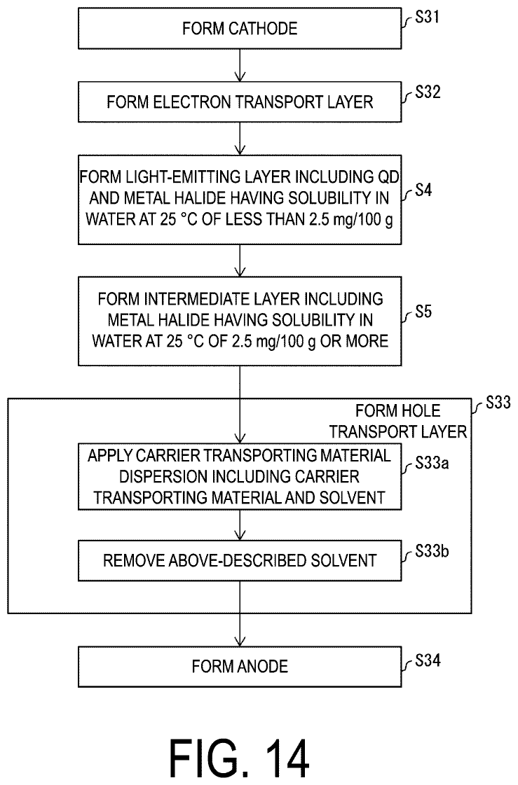

FIG. 14 is a flowchart showing an example of a manufacturing method of the light-emitting element 1 according to the present modified example.

As shown in FIG. 14, in the present modified example, first, the cathode 3 is formed as a lower layer electrode on a substrate not illustrated (step S31, lower layer electrode formation, cathode formation). Subsequently, the ETL 15 is formed (step S32, electron transport layer formation). Subsequently, the EML 13 including the QD 21 and a metal halide 22 (second metal halide, inorganic ligand) having solubility in water at 25° C. of less than 2.5 mg/100 g is formed (step S4, light-emitting layer formation). Subsequently, the IL 14 including a metal halide 31 (first metal halide) having solubility in water at 25° C. of 2.5 mg/100 g or more is formed on the EML 13 (step S5, intermediate layer formation). The HTL 12 is formed on the IL 14 (step S33, carrier transport layer formation, hole transport layer formation). In step S33, as shown in FIG. 14, first, the IL 14 is applied with a carrier transporting material dispersion including a carrier transporting material 41′ and a solvent (first solvent), thereby forming a coating film of the carrier transporting material dispersion (step S33a, carrier transporting material dispersion application). Subsequently, the coating film is heated or the like to remove the solvent included in the coating film, that is, the solvent (first solvent) included in the applied carrier transporting material dispersion (step S33b, first solvent removal). This forms the HTL 12 including the carrier transporting material 41′ as a carrier transporting material on the IL 14. Subsequently, the anode 2 is formed as an upper layer electrode on the HTL 12 (step S34, upper layer electrode formation, anode formation).

In this case, the cathode 3 can be formed by depositing the conductive material on a substrate not illustrated, for example, by a vapor deposition method, a sputtering method, or the like. The anode 2 can be formed by depositing the conductive material on the HTL 12 by a vapor deposition method, sputtering, or the like. Step S31 can be performed similarly to step S6 except that a layer serving as a base is different, and step S33 can be performed similarly to step S1. Step S32 can be performed similarly to step S7 except that a layer serving as a base is different, and step S33 can be performed similarly to step S3.

In the present modified example, in place of the ETL 15 including the carrier transporting material 41, the HTL 12 including the carrier transporting material 41′ is formed on the IL 14. As the carrier transporting material 41′, for example, a hole transporting material such as NiO, WO₃, or MoO₃ is used.

In this manner, also in the present modified example, it is preferable that the carrier transporting material 41′ is a metal oxide, and the carrier transporting material dispersion including the carrier transporting material 41′ has an isoelectric point of pH7 or more. Note that also in the present modified example, the metal oxide is used as a metal oxide nanoparticle.

In the present embodiment, in the carrier transporting material dispersion application (step S33a), the HTL 12 is formed while dissolving a part of the IL 14 by the solvent included in the carrier transporting material dispersion. In the carrier transporting material dispersion application, the IL 14 is dissolved by 2 nm or more with the solvent. As the solvent, a polar solvent similar to the solvent 42 can be used. In this manner, in step S33, the HTL 12 is formed similarly to step S6 except that the carrier transporting material dispersion including the carrier transporting material 41′ is used in place of the carrier transporting material dispersion 43 including the carrier transporting material 41 in step S6. In this manner, the CTL formed on the IL 14 may be the HTL, and the ETL can be read as the HTL in step S6 except for the specific materials as described above. Note that also in the present modified example, the EML 13 may be formed by the method shown in FIG. 5 or may be formed by the method shown in FIG. 6.

The light-emitting element 1 manufactured by the manufacturing method for a light-emitting element according to the present modified example includes the EML 13 including the QD 21, the metal halide 22 (second metal halide), and the metal halide 31 (first metal halide) as described above, and has a configuration in which the IL 14 including the metal halide 31 and the HTL 12 including the carrier transporting material 41′ as the CTL including the carrier transporting material are provided adjacent to each other in this order from the EML 13 side.

According to the present modified example, as described above, since the IL 14 including the metal halide 31 and the HTL 12 including the carrier transporting material 41′ are provided adjacent to each other in this order from the EML 13 side, the wettability of the carrier transporting material dispersion that is a coating liquid including the carrier transporting material 41′ with respect to the EML 13 at the time of forming the HTL 12 can be improved. As a result, the light-emitting element 1 having good uniformity of the layer thickness and excellent light-emission characteristics and reliability can be provided.

In the present modified example, by making the band gaps of the metal halide 22 and the metal halide 31 greater than the band gap of the shell 21b, hole injection from the HTL 12 to the EML 13 can be suppressed.

### Second Modified Example

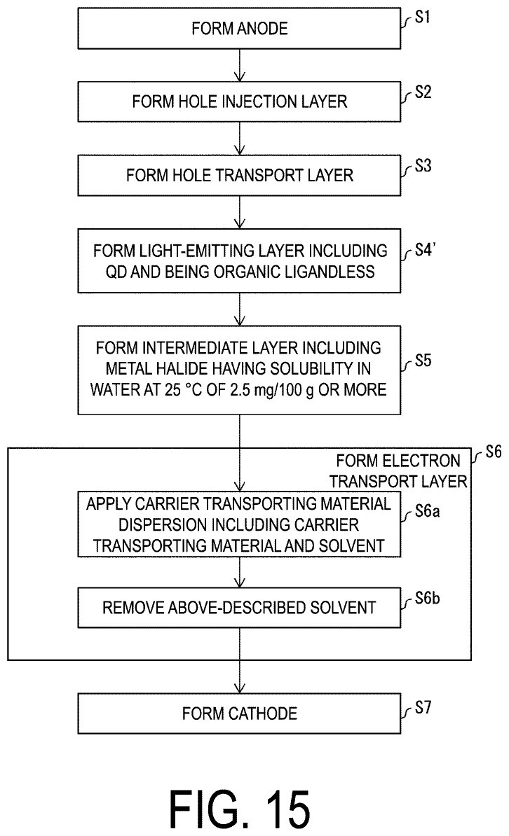

FIG. 15 is a flowchart showing an example of a manufacturing method for the light-emitting element 1 according to the present modified example.

As shown in FIG. 15, the manufacturing method of the light-emitting element 1 according to the present modified example is the same as the manufacturing method for the light-emitting element 1 shown in FIG. 1 except that step S4′ is performed in place of step S4 shown in FIG. 1. In step S4′, an EML including the QD 21 and the metal halide 22 is formed as the EML 13. Therefore, in the present modified example, as illustrated in FIGS. 15 and 2, first, steps SI to S3 are performed similarly to FIG. 1. Subsequently, the EML 13 including the QD 21 and being organic ligandless is formed (step S4′, light-emitting layer formation). Subsequently, steps S5 to S7 similar to steps S5 to S7 shown in FIG. 1 are performed. In step S4′, for example, as described above, the EML 13 of organic ligandless can be formed by appropriately adjusting the ligand substitution conditions in step S12 (ligand substitution) in the light-emitting layer formation shown in FIG. 5.

As described above, after step S15 shown in FIG. 5, additional ligand substitution may be further performed by performing similar process to steps S23 to S26 shown in FIG. 6. Due to this, the organic ligand 23 can be removed by increasing the ligand substitution amount to form the EML 13 of organic ligandless.

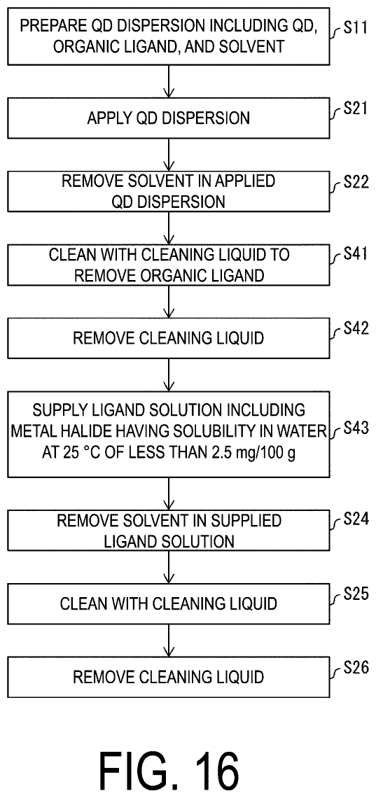

FIG. 16 is a flowchart showing another example of the light-emitting layer formation according to the present modified example.

In the light-emitting layer formation shown in FIG. 16, first, steps S11 to S22 are performed similarly to FIG. 6. That is, in the light-emitting layer formation, first, as shown in FIG. 16, step S11 similar to step S11 shown in FIGS. 5 and 6 is performed to prepare a first QD dispersion including the QD 21, the organic ligand 23 coordinated to the QD 21, and the nonpolar solvent as the second solvent (step S11, first QD dispersion preparation). Subsequently, the first QD dispersion is applied onto the HTL 12 to form a coating film of the first QD dispersion (step S21, first QD dispersion application). Subsequently, the coating film is heated and dried or the like to once remove the solvent included in the applied first QD dispersion (step S22, solvent removal). This forms the EML 13 including the QD 21 and the organic ligand 23 coordinated to the QD 21. Thereafter, in the light-emitting layer formation shown in FIG. 16, the EML 13 is cleaned with a cleaning liquid, thereby removing the organic ligand 23 included in the EML 13 (step S41, organic ligand removal, cleaning).

The removal rate of the organic ligand 23 can be adjusted by, for example, a cleaning time, a supply amount of the cleaning liquid, and the like. In the present embodiment, in step S41, as described above, the absorption spectrum derived from the organic ligand is confirmed by the FT-IR method, and the EML 13 is cleaned until it can be confirmed that “an absorption spectrum derived from an organic ligand cannot be detected by the FT-IR, that is, measurement intensity is equal to or less than noise”.

Note that the cleaning liquid may be a solvent that can remove the organic ligand 23 included in the EML 13. More specifically, the cleaning liquid may be a solvent that dissolves the organic ligand 23 coordinated to the QD 21 and the excess organic ligand 23 not coordinated to the QD 21. Examples of the cleaning liquid include alcohols such as methanol and ethanol.

Thereafter, the EML 13 is heated and dried or the like to remove the solvent included in the EML 13, that is, the cleaning liquid (step S42, cleaning liquid removal). This forms the EML 13 of organic ligandless.

Subsequently, the EML 13 from which the organic ligand 23 has been removed is supplied with a ligand solution including the metal halide 22 and a polar solvent as a solvent (solvent of the ligand solution) to bring the ligand solution and the EML 13 into contact with each other. Note that the supply of the ligand solution can be performed similarly to step S23, for example. However, in the present modified example, the organic ligand 23 is removed in advance as described above. Therefore, in step S42, not ligand substitution but ligand impartment is performed.

Subsequently, steps S24 to S26 similar to steps S24 to S26 shown in FIG. 6 are performed. This can form the EML 13 of organic ligandless including the QD 21 and the metal halide 22 present on the surface of the QD 21.

As described above, the light-emitting layer formation may include the first QD dispersion preparation (step S11) of preparing a QD dispersion (first QD dispersion) including the QD 21, the organic ligand 23, and a solvent (second solvent), and removing the organic ligand 23 before applying the first QD dispersion or after applying the first QD dispersion. As described above, by removing the organic ligand 23 before applying the first QD dispersion or after applying the first QD dispersion, it is possible to form the EML 13 including the QD 21 and being organic ligandless.

Note that in the light-emitting layer formation shown in FIG. 16, as described above, the case where steps S43 to S26 are subsequently performed after step S42 to form the EML 13 of organic ligandless including the metal halide 22 has been described as an example. However, the present modified example is not limited to this, and the IL 14 may be formed on the EML 13 of organic ligandless obtained in step S42 by performing step S6 shown in FIG. 15 after step S42. In this case, finally, the light-emitting element 1 including the EML 13 including only the metal halide 31 as the metal halide can be manufactured.

In any case, according to the present modified example, it is possible to provide the light-emitting element 1 including the EML 13 of organic ligandless including the QD 21 and the metal halide 31 (first metal halide), in which the IL 14 including the metal halide 31 and the ETL 15 including the carrier transporting material 41 as the CTL including the carrier transporting material are provided adjacent to each other in this order from the EML 13 side.

As described above, also in the present modified example, since the IL 14 including the metal halide 31 and the ETL 15 including the carrier transporting material 41 are provided adjacent to each other in this order from the EML 13 side, the wettability of the carrier transporting material dispersion 43 at the time of forming the ETL 15 can be improved. As a result, the light-emitting element 1 having good uniformity of the layer thickness and excellent light-emission characteristics and reliability can be provided.

Note that as described above, also in the present modified example, the EML 13 may further include the metal halide 22 (second metal halide) in addition to the QD 21 and the metal halide 31. Also in the present modified example, similarly to the first modified example, the HTL 12 including the carrier transporting material 41′ may be formed on the IL 14 as the CTL including the carrier transporting material.

### Second Embodiment

Differences from the first embodiment will be described in the present embodiment.

The light-emitting element manufacturing method according to the present embodiment includes: forming an EML; and forming a CTL on the EML, in which forming the CTL includes applying the EML with a carrier transporting material dispersion including a carrier transporting material, a first solvent, and a first metal halide, and removing the first solvent. In applying the carrier transporting material dispersion, a metal halide having solubility in water at 25° C. of 2.5 mg/100 g or more is used as the first metal halide, and in forming the EML, as the EML, (1) an EML including a QD and a second metal halide having solubility in water at 25° C. of less than 2.5 mg/100 g is formed, or (2) an EML including the QD and being organic ligandless is formed.

Hereinafter, a case of forming an EML including a QD and the second metal halide as the EML in forming the EML will be described as an example. In the following, a case where the CTL formed on the EML is an ETL will be described as an example. In the following description, a case where the light-emitting element has a conventional structure in which an anode is a lower layer electrode and a cathode is an upper layer electrode, and includes the HIL, the HTL, the EML, and the ETL as function layers between the anode and the cathode will be described as an example.

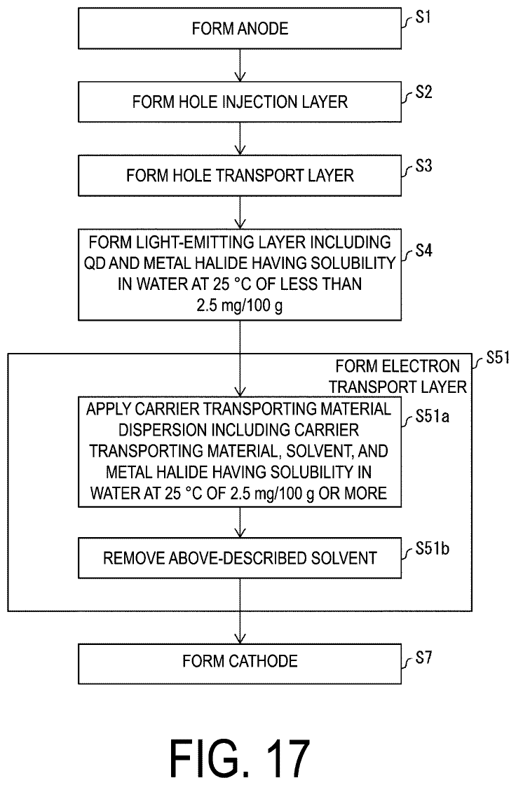

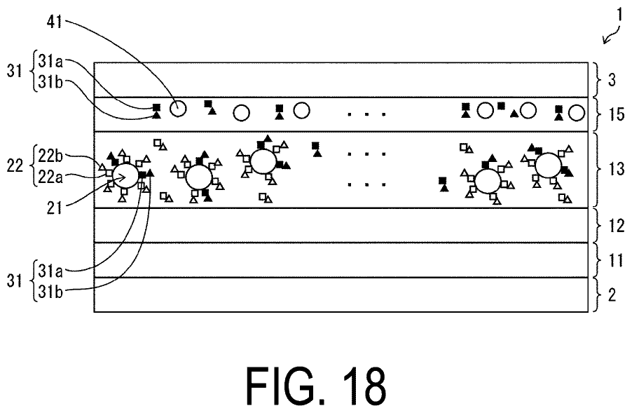

Hereinafter, a specific description will be given with reference to the drawings. FIG. 17 is a flowchart showing an example of a manufacturing method for the light-emitting element 1 according to the present embodiment. FIG. 18 is a cross-sectional view illustrating a schematic configuration of the light-emitting element 1 according to the present embodiment. Note that in the following, for convenience of description, members having the same functions as those of the members described in the first embodiment are denoted by the same reference signs, and the description thereof will not be repeated. It goes without saying that similar modifications to those of the first embodiment can be made even unless otherwise explained.

As illustrated in FIG. 18, the light-emitting element 1 according to the present embodiment has a configuration in which, as an example, the anode 2, the HIL 11, the HTL 12, the EML 13, the ETL 15, and the cathode 3 are provided in this order from the lower layer side (e.g., a side of a support body not illustrated such as a substrate). However, the ETL 15 according to the present embodiment is layered on the EML 13 adjacent to the EML 13, and includes the carrier transporting material 41 and the metal halide 31 (first metal halide). Note that also in the present embodiment, although illustration and description are omitted, the light-emitting element 1 may include a function layer not illustrated other than the HIL 11, the HTL 12, the EML 13, and the ETL 15 between the anode 2 and the cathode 3.

In the manufacturing method for the light-emitting element 1 according to the present embodiment, as shown in FIGS. 17 and 18, for example, first, steps S1 to S4 are performed similarly to FIG. 1. Note that also in the present embodiment, in step S4, the EML 13 may be formed by the method shown in FIG. 5 or may be formed by the method shown in FIG. 6.

In the present embodiment, the ETL 15 is formed on the EML 13 after step S4 (step S51, carrier transport layer formation, electron transport layer formation). In step S51, as shown in FIG. 17, first, the EML 13 is applied with a carrier transporting material dispersion including the carrier transporting material 41, a solvent (first solvent), and the metal halide 31, thereby forming a coating film of the carrier transporting material dispersion (step S51a, carrier transporting material dispersion application). Subsequently, the coating film is heated or the like to remove the solvent included in the coating film, that is, the solvent (first solvent) included in the applied carrier transporting material dispersion (step S51b, first solvent removal). Due to this, the ETL 15 including the carrier transporting material 41 and the metal halide 31 is formed on the EML 13. Subsequently, step S7 similar to step S7 shown in FIG. 1 is performed to form the cathode 3 as the upper layer electrode on the ETL 15. This forms the light-emitting element 1 illustrated in FIG. 18.

In this manner, in the present embodiment, the EML 13 is applied with the carrier transporting material dispersion including the carrier transporting material 41, the solvent (first solvent), and the metal halide 31, thereby forming the ETL 15 including the carrier transporting material 41 and the metal halide 31. As described above, the metal halide has a size allowing to pass through a gap between the QDs 21 in the EML 13.

Therefore, in the present embodiment, as described above, when the EML 13 is applied with the carrier transporting material dispersion, the metal halide 31 included in the carrier transporting material dispersion enters the EML 13. Due to this, some of the ligands (the organic ligand 23 when including the metal halide 22 and the organic ligand 23) on the surface of the QD 21 in the EML 13 is substituted with the metal halide 31. At the same time, in the present embodiment, a coating film of the carrier transporting material dispersion is formed on the EML 13.

Therefore, according to the present embodiment, as described above, the wettability of the carrier transporting material dispersion with respect to the EML 13 can be improved by applying the EML 13 with the carrier transporting material dispersion including the carrier transporting material 41, the solvent (first solvent), and the metal halide 31. As a result, the light-emitting element 1 having good uniformity of the layer thickness and excellent light-emission characteristics and reliability can be manufactured.

According to the present embodiment, as described above, the EML 13 is applied with the carrier transporting material dispersion including the carrier transporting material 41, the solvent (first solvent), and the metal halide 31, whereby the ETL 15 can be directly formed on the EML 13. Therefore, as compared with the first embodiment, the number of processes can be reduced, the manufacturing process can be simplified, and the time and cost required for manufacturing can be reduced.

Moreover, in the present embodiment, the carrier transporting material dispersion can be applied in a state where the carrier transporting material 41 is modified with the metal halide 31. Therefore, the dispersibility of the carrier transporting material 41 can be improved. The present embodiment is particularly effective when the EML 13 is provided with a CTL such as the ETL 15 as described above in the process.

Note that in the present embodiment, since the ETL 15 includes the metal halide 31, the formation of the ETL 15 requires selection of the metal halide 31 corresponding to the metal halide 22 on the QD 21 surface in the EML 13 serving as a base. In the present embodiment, by using a metal halide having the same halogen for the metal halide 22 and the metal halide 31, even if the metal halide 31 included in the metal halide-including liquid used for formation of the ETL 15 enters the EML 13, the type of halide ions included in the EML 13 does not increase. Therefore, by using a metal halide having the same halogen species for the EML 13 and the ETL 15, the influence on the QD 21 is small, and the decrease of the light-emission characteristics can be suppressed.

The light-emitting element 1 manufactured by the manufacturing method for a light-emitting element according to the present embodiment includes the EML 13 including the QD 21, the metal halide 22 (second metal halide), and the metal halide 31 (first metal halide) as described above, and has a configuration in which the EML 13 is provided with, adjacent to the EML 13, the ETL 15 including the carrier transporting material 41 and the metal halide 31 as the CTL including the carrier transporting material and the metal halide 31 (first metal halide).

According to the present embodiment, as described above, since the ETL 15 including the carrier transporting material 41 and the metal halide 31 is provided adjacent to the EML 13, the wettability of the coating liquid (carrier transporting material dispersion) including the carrier transporting material 41 with respect to the EML 13 at the time of forming the ETL 15 can be improved. As a result, the light-emitting element 1 having good uniformity of the layer thickness and excellent light-emission characteristics and reliability can be provided.

Note that also in the present embodiment, as described above, when the EML 13 including the metal halide 22 is formed, the EML 13 further includes the metal halide 31 in addition to the metal halide 22 as illustrated in FIG. 18. Therefore, also in the present embodiment, both the anion 22a and the anion 31a exist as ligands on the surface of the QD 21.

Therefore, in the present embodiment, as described above, by using a metal halide having the same halogen for the EML 13 and the ETL 15, even if the metal halide 31 included in the carrier transporting material dispersion used for formation of the ETL 15 enters the EML 13, the type of halide ions included in the EML 13 does not increase. Therefore, by using a metal halide having the same halogen species for the EML 13 and the ETL 15, the influence on the QD 21 is small, and the decrease of the light-emission characteristics can be suppressed.

Note that in the present embodiment, the layer thickness of each layer of the light-emitting element 1 may be set in the same manner as a known layer thickness. However, when a wide-gap metal halide is used as the metal halide 31, carrier injection from the ETL 15 is suppressed. Therefore, it is desirable to appropriately adjust the layer thickness of the ETL 15 as necessary.

As described above, even when the carrier transporting material dispersion includes the carrier transporting material 41, the solvent (first solvent), and the metal halide 31, the carrier transporting material 41 is desirably a metal oxide for the same reason as the reason described in the first embodiment, and the isoelectric point of the carrier transporting material dispersion is preferably pH7 or more.

### First Modified Example

In FIGS. 17 and 18, a case where the light-emitting element 1 has a conventional structure in which the anode 2 is a lower layer electrode has been described as an example. However, also in the present embodiment, the light-emitting element 1 may have an inverted structure in which the cathode 3 is a lower layer electrode. The CTL formed on the EML 13 is not limited to the ETL, and may be the HTL.

Therefore, although not illustrated, the light-emitting element 1 according to the present embodiment may have an inverted structure in which the cathode 3 is a lower layer electrode and the anode 2 is an upper layer electrode, and as an example, may have a configuration in which the cathode 3, the ETL 15, the EML 13, the HTL 12, and the anode 2 are provided in this order from the lower layer side (e.g., a support body side not illustrated such as a substrate). Note that although illustration and description are omitted, also in the present modified example, the light-emitting element 1 may include a function layer not illustrated between the anode 2 and the cathode 3.

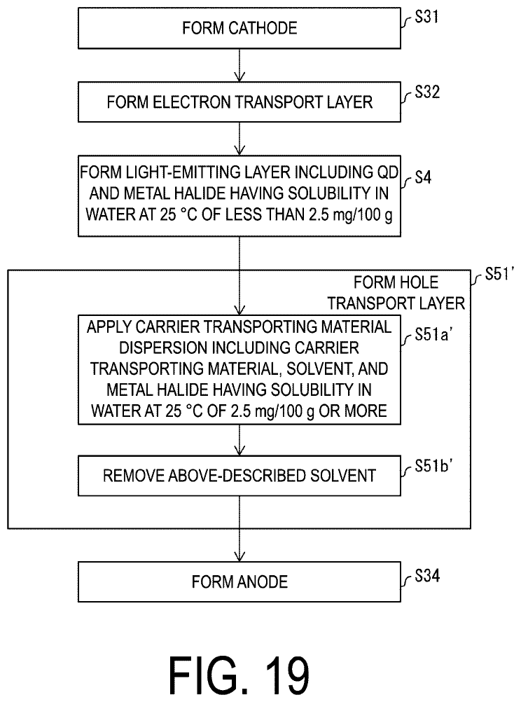

FIG. 19 is a flowchart showing an example of a manufacturing method of the light-emitting element 1 according to the present modified example.

As shown in FIG. 19, in the present modified example, first, similarly to FIG. 14, step S31, step S32, and step S4 are performed in this order. Note that also in the present modified example, the EML 13 may be formed by the method shown in FIG. 5 or may be formed by the method shown in FIG. 6. Subsequently, the HTL 12 is formed on the EML 13 formed in step S4 (step S51′, carrier transport layer formation, hole transport layer formation). In step S51′, as shown in FIG. 19, first, the EML 13 is applied with a carrier transporting material dispersion including the carrier transporting material 41′, a solvent (first solvent), and the metal halide 31, thereby forming a coating film of the carrier transporting material dispersion (step S51a′, carrier transporting material dispersion application). Subsequently, the coating film is heated or the like to remove the solvent included in the coating film, that is, the solvent (first solvent) included in the applied carrier transporting material dispersion (step S51b′, first solvent removal). Due to this, the HTL 12 including the carrier transporting material 41′ and the metal halide 31 is formed on the EML 13. Subsequently, step S34 similar to step S34 shown in FIG. 14 is performed to form the anode 2 as an upper layer electrode on the HTL 12. This forms the light-emitting element 1 according to the present modified example.

As described above, in the present modified example, the EML 13 is applied with the carrier transporting material dispersion including the carrier transporting material 41′, the solvent (first solvent), and the metal halide 31, thereby forming the HTL 12 including the carrier transporting material 41′ and the metal halide 31. As described above, the metal halide has a size allowing to pass through a gap between the QDs 21 in the EML 13.

Therefore, also in the present modified example, as described above, when the EML 13 is applied with the carrier transporting material dispersion, the metal halide 31 included in the carrier transporting material dispersion enters the EML 13. Due to this, some of the ligands (the organic ligand 23 when the EML 13 includes the metal halide 22 and the organic ligand 23) on the surface of the QD 21 in the EML 13 is substituted with the metal halide 31. At the same time, also in the present modified example, a coating film of the carrier transporting material dispersion is formed on the EML 13.

Therefore, according to the present modified example, as described above, the wettability of the carrier transporting material dispersion with respect to the EML 13 can be improved by applying the EML 13 with the carrier transporting material dispersion including the carrier transporting material 41′, the solvent (first solvent), and the metal halide 31. As a result, the light-emitting element 1 having good uniformity of the layer thickness and excellent light-emission characteristics and reliability can be manufactured.

According to the present modified example, as described above, the EML 13 is applied with the carrier transporting material dispersion including the carrier transporting material 41′, the solvent (first solvent), and the metal halide 31, whereby the HTL 12 can be directly formed on the EML 13. Therefore, as compared with the first modified example of the first embodiment, the number of processes can be reduced, the manufacturing process can be simplified, and the time and cost required for manufacturing can be reduced.

Moreover, in the present modified example, the carrier transporting material dispersion can be applied in a state where the carrier transporting material 41′ is modified with the metal halide 31. Therefore, the dispersibility of the carrier transporting material 41′ can be improved.

Note that also in the present modified example, for the same reason as the reason described in the first embodiment, it is preferable that the carrier transporting material 41′ is a metal oxide, and the carrier transporting material dispersion including the carrier transporting material has an isoelectric point of pH7 or more. Also in the present modified example, the metal oxide is used as a metal oxide nanoparticle.

In the present modified example, the HTL 12 is formed on the EML 13 similarly to step S51 except that the carrier transporting material 41′ is used as the carrier transporting material in step S51′. In this manner, the CTL formed on the EML 13 may be the HTL, and the ETL can be read as the HTL in step S51 except for the specific materials as described above.

The light-emitting element 1 manufactured by the light-emitting element manufacturing method according to the present modified example includes the EML 13 including the QD 21, the metal halide 22 (second metal halide), and the metal halide 31 (first metal halide) as described above, and has a configuration in which the EML 13 is provided with, adjacent to the EML 13, the HTL 12 including the carrier transporting material 41′ and the metal halide 31 as the CTL including the carrier transporting material and the metal halide 31 (first metal halide).

According to the present modified example, as described above, since the HTL 12 including the carrier transporting material 41′ and the metal halide 31 is provided adjacent to the EML 13, the wettability of the coating liquid (carrier transporting material dispersion) including the carrier transporting material 41′ with respect to the EML 13 at the time of forming the ETL 15 can be improved, and the light-emitting element 1 having good uniformity of the layer thickness and excellent light-emission characteristics and reliability can be provided.

In the present modified example, by making the band gaps of the metal halide 22 and the metal halide 31 greater than the band gap of the shell 21b, hole injection from the HTL 12 to the EML 13 can be suppressed.

### Second Modified Example

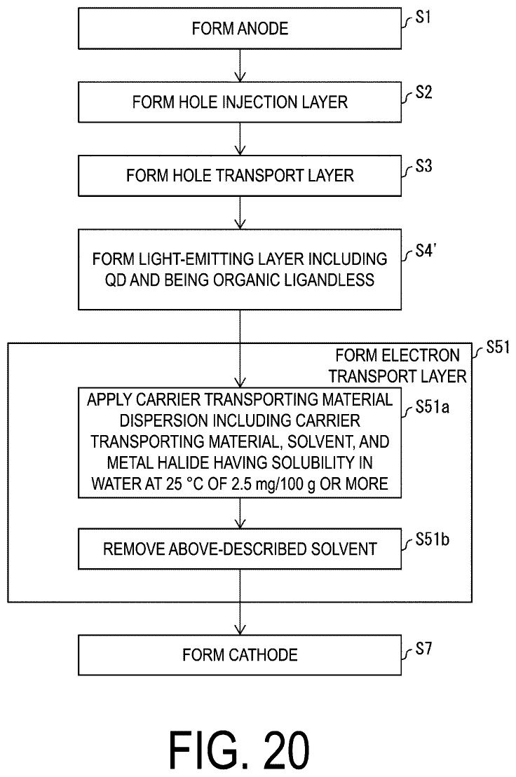

FIG. 20 is a flowchart showing an example of a manufacturing method of the light-emitting element 1 according to the present modified example.

As shown in FIG. 20, the manufacturing method of the light-emitting element 1 according to the present modified example is the same as the manufacturing method of the light-emitting element 1 shown in FIG. 17 except that step S4′ similar to step S4′ shown in FIG. 15 is performed in place of step S4 shown in FIG. 17. Also in the present modified example, in step S4′, for example, the EML 13 of organic ligandless may be formed by appropriately adjusting the ligand substitution conditions in step S12 (ligand substitution) in the light-emitting layer formation shown in FIG. 5. After step S15 shown in FIG. 5, the EML 13 of organic ligandless may be formed by performing additional ligand substitution such as performing similar processes to steps S23 to S26 shown in FIG. 6. The EML 13 of organic ligandless may be formed by using the method shown in FIG. 16.

As described above, also in the present modified example, the light-emitting layer formation may include the first QD dispersion preparation (step S11) of preparing a QD dispersion (first QD dispersion) including the QD 21, the organic ligand 23, and a solvent (second solvent), and removing the organic ligand 23 before applying the first QD dispersion or after applying the first QD dispersion. As described above, by removing the organic ligand 23 before applying the first QD dispersion or after applying the first QD dispersion, it is possible to form the EML 13 including the QD 21 and being organic ligandless.

In any case, according to the present modified example, it is possible to provide the light-emitting element 1 including the EML 13 of organic ligandless including the QD 21 and the metal halide 31 (first metal halide), in which the EML 13 is provided with, adjacent to the EML 13, the ETL 15 including the carrier transporting material 41 and the metal halide 31 (first metal halide) as the CTL including the carrier transporting material and the metal halide 31.

As described above, also in the present modified example, since the ETL 15 including the carrier transporting material 41 and the metal halide 31 is provided adjacent to the EML 13, the wettability of the coating liquid (carrier transporting material dispersion) including the carrier transporting material 41 with respect to the EML 13 at the time of forming the ETL 15 can be improved. As a result, the light-emitting element 1 having good uniformity of the layer thickness and excellent light-emission characteristics and reliability can be provided.

Note that as described above, also in the present modified example, the EML 13 may further include the metal halide 22 (second metal halide) in addition to the QD 21 and the metal halide 31. Also in the present modified example, as in the first modified example, the HTL 12 including the carrier transporting material 41′ and the metal halide 31 may be formed as the CTL on the EML 13.

The disclosure is not limited to the embodiments described above, and various modifications can be made within the scope of the claims. Embodiments obtained by appropriately combining technical approaches disclosed in the different embodiments also fall within the technical scope of the disclosure. New technical approaches can be formed by combining the technical means disclosed in each embodiment.

### REFERENCE SIGNS LIST

1 Light-emitting element
2 Anode
3 Cathode
12 Carrier transport layer (HTL)
15 Carrier transport layer (ETL)
13 Light-emitting layer (EML)
14 Intermediate layer (IL)
21 QD
21a Core
21b Shell
22 Metal halide (second metal halide)
23 Organic ligand
31 Metal halide (first metal halide)
41, 41′ Carrier transporting material
42 Solvent (first solvent)
43 Carrier transporting material dispersion

1. A manufacturing method for a light-emitting element, comprising:
forming a light-emitting layer including a quantum dot;
forming an intermediate layer including a first metal halide on the light-emitting layer; and
forming a carrier transpotation layer by applying a carrier transporting material dispersion including a carrier transporting material and a first solvent onto the intermediate layer, and subsequently
removing the first solvent,
wherein solublity of the first metal halide in water at 25° C. is 2.5 mg/100 g or more,
wherein the manufacturing method satisfies at least one of a first condition that the light-emitting layer further contains a second metal halide with solubility in water at 25° C. of less than 2.5 mg/100 g, or a second condition that the quantum dot in the light-emitting layer is organic ligandless.

2. The manufacturing method for a light-emitting element according to claim 1,
wherein the manufacturing method satisfies the first condition.

3. The manufacturing method for a light-emitting element according to claim 2,
wherein the forming the light-emitting layer includes
preparing a quantum dot dispersion including the quantum dot, an organic ligand of the quantum dot, and a second solvent, and
substituting the organic ligand with the second metal halide before applying the quantum dot dispersion or after applying the quantum dot dispersion.

4. The manufacturing method for a light-emitting element according to claim 2,
wherein a halogen of the first metal halide is a same as a halogen of the second metal halide.

5. The manufacturing method for a light-emitting element according to claim 1,
wherein the manufacturing method satisfies the second condition.

6. (canceled)

7. The manufacturing method for a light-emitting element according to claim 1,
wherein in the applying the carrier transporting material dispersion, the intermediate layer is dissolved by 2 nm or more by the first solvent, and
where a layer thickness of the intermediate layer dissolved by the first solvent is Tnm (T≥2), in the forming the intermediate layer, the intermediate layer having a layer thickness of 2+Tnm or more is formed.

8. A manufacturing method for a light-emitting element, comprising:
forming a light-emitting layer including a quantum dot; and
forming a carrier transpotation layer by applying a carrier transporting material dispersion including a carrier transporting material, a first solvent, and a first metal halide onto the light-emitting layer, and subsequently
removing the first solvent, wherein s
a metal halide with solubility in water at 25° C. is 2.5 mg/100 g or more, and
wherein the manufacturing method satisfies at least one of a first condition that the light-emitting layer further contains a second metal halide with solubility in water at 25° C. of less than 2.5 mg/100 g, or a second condition that the quantum dot in the light-emitting layer is organic ligandless.

9. The manufacturing method for a light-emitting element according to claim 8,
wherein the manufacturing method satisfies the first condition.

10. The manufacturing method for a light-emitting element according to claim 9,
wherein the forming the light-emitting layer includes
preparing a quantum dot dispersion including the quantum dot, an organic ligand, and a second solvent, and
substituting the organic ligand with the second metal halide before applying the quantum dot dispersion or after applying the quantum dot dispersion.

11. The manufacturing method for a light-emitting element, according to claim 9,
wherein a halogen of a metal halide is a same as a halogen of the second metal halide.

12. The manufacturing method for a light-emitting element according to claim 8,
wherein the manufacturing method satisfies the second condition.

13. The manufacturing method for a light-emitting element according to claim 12,
wherein forming the light-emitting layer includes
preparing a quantum dot dispersion including the quantum dot, an organic ligand of the quantum dot, and a second solvent, and
removing the organic ligand before applying the quantum dot dispersion or after applying the quantum dot dispersion.

14. The manufacturing method for a light-emitting element according to claim 1,
wherein the quantum dot includes a core and a shell, and
each of a band gap of the first metal halide and a band gap of the second metal halide is greater than a band gap of the shell.

15. The manufacturing method for a light-emitting element according to claim 1,
wherein the first metal halide is at least one type selected from the group consisting of LiF, NaF, KF, RbF, CsF, BeF₂, MgF₂, SrF₂, BaF₂, AlF₃, InF₃, PbF₂, LiCl, NaCl, KCl, RbCl, CsCl, BeCl₂, MgCl₂, CaCl₂, SrCl₂, BaCl₂, AlCl₃, GaCl₃, LiBr, NaBr, KBr, RbBr, CsBr, BeBr₂, MgBr₂, CaBr₂, SrBr₂, BaBr₂, AlBr₃, SnBr₂, LiI, NaI, KI, RbI, CsI, BeI₂, MgI₂, CaI₂, and SrI₂.

16. The manufacturing method for a light-emitting element according to claim 1,
wherein the carrier transporting material is a metal oxide, and
the carrier transporting material dispersion has an isoelectric point of pH7 or more.

17. A light-emitting element comprising:
a light-emitting layer including a quantum dot and a first metal halide,
wherein the light emitting element satisfies at least one of a first condition that an intermediate layer including the first metal halide and a carrier transport layer including a carrier transporting material are provided on the light emitting layer in this order from the light-emitting layer side so as to be adjacent to each other, or a second condition that a carrier transport layer including a carrier transporting material and the first metal halide is provided on the light-emitting layer, and
solubility of the first metal halide in water at 25° C. is 2.5 mg/100 g or more.

18. The light-emitting element according to claim 17,
wherein the light-emitting layer further includes a second metal halide with solubility in water at 25° C. of less than 2.5 mg/100 g.

19. The light-emitting element according to claim 17,
wherein the light emitting element satisfies the first condition.

20. The light-emitting element according to claim 19,
wherein the intermediate layer has a layer thickness of 2 nm or more.

21. The light-emitting element according to claim 17,
wherein the light emitting element satisfies the second condition.
